(19) United States
(12) Patent Application Publication
(10) Pub. No.: US 2025/0054819 A1
(43) Pub. Date: Feb. 13, 2025

(54) STIFFENER ASSEMBLY AND METHOD FOR MAKING A SEMICONDUCTOR ASSEMBLY

(71) Applicant: Intel Corporation, Santa Clara, CA (US)

(72) Inventors: Seok Ling LIM, Kulim (MY); Eng Huat GOH, Paya Terubong (MY); Kavitha NAGARAJAN, Bangalore (IN); Kang Eu ONG, Simpang Ampat (MY); Min Suet LIM, Gelugor (MY)

(21) Appl. No.: 18/447,314

(22) Filed: Aug. 10, 2023

(51) Int. Cl. H01L 23/053; H01L 21/48; H01L 23/16; H01L 23/544; H01L 25/065

(52) U.S. Cl. CPC H01L 23/053; H01L 21/4817; H01L 23/16; H01L 23/544; H01L 25/0652; H01L 24/16; H01L 24/32; H01L 24/73; H01L 2224/16225; H01L 2224/32225; H01L 2224/73204; H01L 2924/1616; H01L 2924/16251; H01L 2924/16315

(57) ABSTRACT

According to various aspects, there may be provided a stiffener assembly. The stiffener assembly may include a primary stiffener and an auxiliary stiffener. The primary stiffener may include a first engagement arrangement, and the auxiliary stiffener may include a second engagement arrangement. The first engagement arrangement of the primary stiffener and the second engagement arrangement of the auxiliary stiffener may be configured to form a detachable joint with each other, thereby enabling the auxiliary stiffener to be releasably connected to the primary stiffener for reinforcing the primary stiffener.

### BACKGROUND

Stiffeners are commonly used in the semiconductor industry, to provide additional support and rigidity to semiconductor devices.

It is typically desirable to have a large and thick stiffener, with substantial width and height, to effectively counteract warpage of semiconductor devices.

However, such a design choice often necessitates trade-offs in terms of the overall size and dimensions of the semiconductor devices.

Moreover, the presence of a tall stiffener can create interference with a heat spreader or other components within semiconductor devices.

Therefore, there may be a need for an improved stiffener that addresses warpage issues associated with semiconductor devices while minimizing the impact on their form factor and any adverse impact on the functionality of other components within a semiconductor assembly.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. In the following description, various aspects are described with reference to the following drawings.

FIG. 1A is a schematic diagram showing a primary stiffener, on a substrate of a semiconductor assembly, according to various aspects of the present disclosure;

FIG. 1B is a schematic diagram showing the primary stiffener of FIG. 1A detachably attached to an auxiliary stiffener, according to various aspects of the present disclosure;

FIG. 1C is a schematic diagram showing the auxiliary stiffener detached from the primary stiffener, according to various aspects of the present disclosure;

FIG. 2A is a perspective view of a primary stiffener attached to a peripheral region of a substrate of a stiffener assembly and an auxiliary stiffener detached from the primary stiffener, according to various aspects of the present disclosure;

FIG. 2B is a close-up perspective view of a female snap-fit connector of a first engagement arrangement of the primary stiffener and a male-snap-fit connector of a second engagement arrangement of the auxiliary stiffener, according to various aspects of the present disclosure;

FIG. 2C is a cross-sectional profile of the female snap-fit connector of the first engagement arrangement of the primary stiffener and the male snap-fit connector of the second engagement arrangement of the auxiliary stiffener, according to various aspects of the present disclosure;

FIG. 3A shows a schematic top view of a stiffener assembly with a primary stiffener and a first variant auxiliary stiffener, within a semiconductor assembly, according to various aspects of the present disclosure;

FIG. 3B is a side view of FIG. 3A taken along line A-A, according to various aspects of the present disclosure;

FIG. 4A shows a schematic top view of a stiffener assembly with a primary stiffener and a second variant auxiliary stiffener, within a semiconductor assembly, according to various aspects of the present disclosure;

FIG. 4B is a side view of FIG. 4A taken along line B-B′, according to various aspects of the present disclosure;

FIG. 5A shows a schematic top view of a stiffener assembly with a primary stiffener and a third variant auxiliary stiffener, within a semiconductor assembly, according to various aspects of the present disclosure;

FIG. 5B is a side view of FIG. 5A taken along line C-C′, according to various aspects of the present disclosure;

FIG. 6A shows a top perspective view of a stiffener assembly with a primary stiffener and an auxiliary stiffener having chamfered corner walls, within a semiconductor assembly, according to various aspects of the present disclosure;

FIG. 6B is a side view of FIG. 6A, according to various aspects of the present disclosure;

FIG. 7A to FIG. 7G depict a method or process for assembling a semiconductor assembly, according to various aspects of the present disclosure; and

FIG. 8 is a flow chart of a method, according to various aspects of the present disclosure.

### DETAILED DESCRIPTION

Aspects of the present disclosure described below in context of the apparatus are analogously valid for the respective methods, and vice versa. Furthermore, it will be understood that the aspects described below may be combined, for example, a part of one aspect may be combined with a part of another aspect.

It should be understood that the terms “on”, “over”, “top”, “bottom”, “down”, “side”, “back”, “left”, “right”, “front”, “lateral”, “up” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

Various aspects of the present disclosure generally relate to a multi-component stiffener assembly for a substrate, such as a package substrate.

The multi-component stiffener assembly may include at least one base stiffener member (e.g. at least one primary stiffener) and one or more other reinforcing stiffener members (e.g. auxiliary stiffener or auxiliary stiffener modules).

The at least one base stiffener member and the one or more other reinforcing stiffener members may be assembled (e.g. on the package substrate itself) to form an assembled stiffener assembly for providing required mechanical support to a package substrate, particularly, before and/or when Surface Mounting Technology processes are performed on the package substrate.

To maintain a slim profile, the at least one base stiffener member may be engineered with a relatively short height. The one or more reinforcing stiffener members, on the other hand, may be detachably attached or releasably connected to the at least one base stiffener member (e.g. via a snap-fit latch arrangement or any suitable mechanical fastener) to reinforce the base stiffener member as well as the underlying package substrate.

Both the base stiffener member and the one or more reinforcing stiffener members may be composed of a same hard and/or rigid material. Alternatively, the one or more reinforcing stiffener members may be composed of a different hard and/or rigid material from the base stiffener member.

Once Surface Mounting Technology processes are completed, the one or more reinforcing stiffener members may be detached or removed from the at least one base stiffener member.

Consequently, the resulting semiconductor package, featuring the aforementioned package substrate, may have a relatively thin profile.

Moreover, the reinforcing stiffener members may be utilized for other base stiffener members and other package substrates, contributing to its reusability. This means that a same set of reinforcing stiffener members may be employed for different base stiffener members and corresponding package substrates, as such, expanding their application across various configurations and designs.

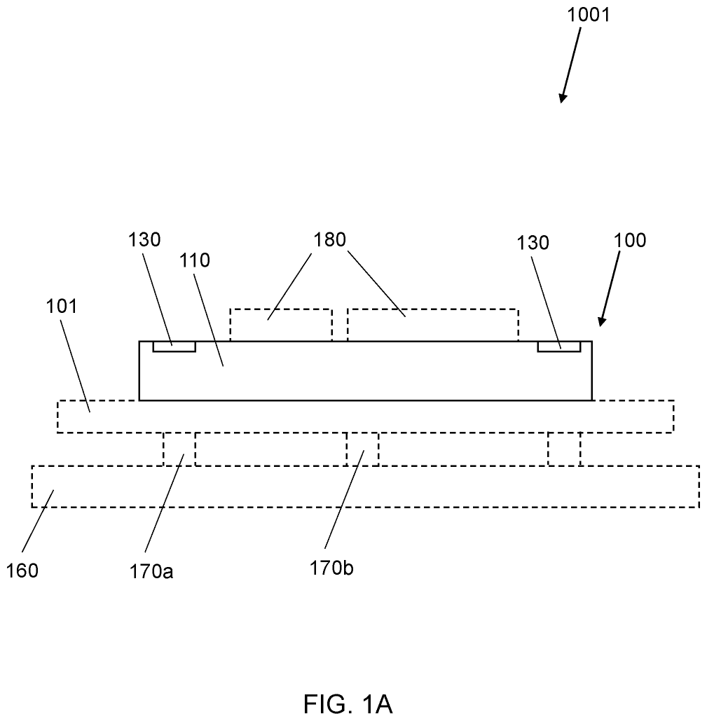

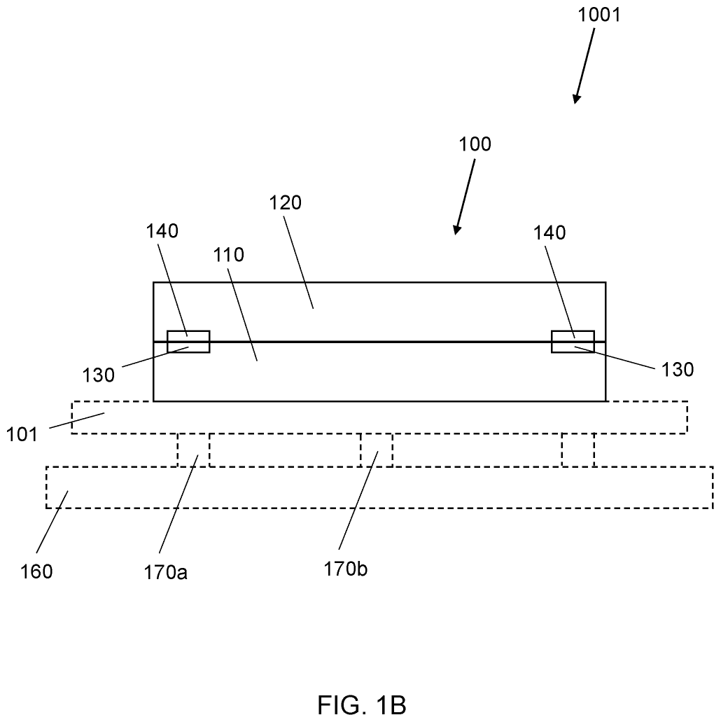

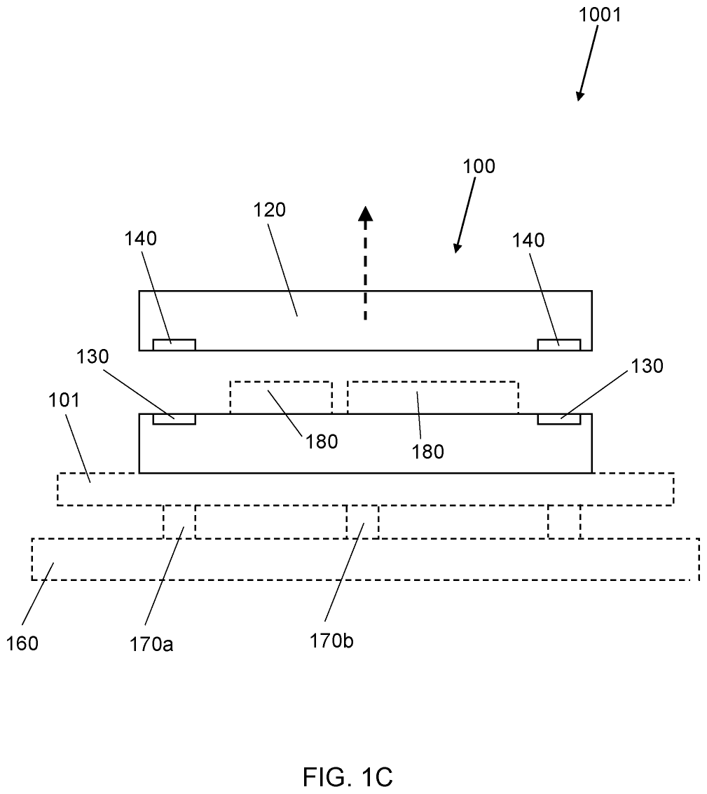

FIG. 1A is a schematic diagram showing a primary stiffener, on a substrate of a semiconductor assembly, according to various aspects of the present disclosure.

According to various aspects, the primary stiffener 110 may be attached or mounted or affixed to a substrate 101 (e.g. a package substrate, a semiconductor package substrate, etc.) of a semiconductor assembly 1001, to provide structural support as a “stiffener” for the substrate 101.

As shown in FIG. 1A, the primary stiffener 110 may include a base surface, at a base portion thereof. The base surface of the primary stiffener 110 may include or may be a flat or level (e.g. a substantially flat or level) surface, which may be aligned with a corresponding flat or level surface (e.g. an upper surface) of the substrate 101 (herein referred to as a “substrate-surface”).

To connect or attach the primary stiffener 110 to the substrate 101, any suitable bonding or attachment techniques or mechanisms may be employed, such as adhesive bonding, mechanical fasteners, soldering, etc.

According to various aspects, the primary stiffener 110 may be configured to provide mechanical support to the substrate 101 when it is attached thereto and may be aimed at minimizing or preventing deformation (e.g. warpage) of the substrate 101, in particular, when the substrate 101 is subjected to external forces and/or heat (e.g. during processes, such as surface mount or reflow processes).

For example, according to various aspects, the primary stiffener 110 may include or may be made or composed of a hard and/or rigid material, such as steel (e.g. stainless steel), which may be harder and/or more rigid than a material the substrate 101 may be composed of. Such a choice of material for the primary stiffener 110 may enable the primary stiffener 110 to provide mechanical support to the attached substrate 101.

As another example, according to various aspects, the primary stiffener 110 may be shaped in a manner which enables it to provide mechanical support to the substrate 101 when it is attached thereto. For instance, the primary stiffener 110 may be shaped as a supportive or strengthening frame or ridge. Such a primary stiffener 110 may be strategically positioned on the substrate 101 to bolster the structure of the substrate 101.

To illustrate, in accordance with various aspects, the primary stiffener 110 may be shaped as a circumferential structure (e.g. an annular structure, a closed-loop brace, a band, etc.), extending across a peripheral region of the substrate 101 on the substrate-surface of the substrate 101. Such a circumferential structure (i.e. primary stiffener 110) may include a plurality of walls, such as linear walls, which may connect or adjoin one another at angles (e.g. perpendicular or substantially perpendicular angles). The plurality of connecting or adjoining walls may surround an opening or central space, e.g. for receiving or positioning one or more other components (e.g. dies, chips, etc.) of the semiconductor assembly 1001 on the substrate 101. According to various aspects, this circumferential structure may enable the primary stiffener 110 to provide mechanical support and rigidity to a substantial portion of the substrate 101, particularly, to at least the peripheral region of the substrate 101.

Alternatively, in accordance with various other aspects, the primary stiffener 110 may shaped as an elongate structure, for example, resembling a single ridge or wall, running along a portion or segment of the substrate-surface of the substrate 101. Such an elongate structure (i.e. primary stiffener 110) may be positioned at a specific side (e.g. a single side) or edge region of the substrate 101, so as to provide mechanical support primarily to that specific side or edge region of the substrate 101.

Furthermore, in various other aspects, the primary stiffener 110 may take on different forms and/or configurations. For instance, the primary stiffener 101 may be or may include a “L”-shaped structure, a “C”-shaped structure, a bracket-shaped (e.g. “[”-shaped) structure, a “T”-shaped structure, or any other regular or irregular-shaped structure. Alternatively, the primary stiffener 101 may include or may be composed of spaced apart modules, such as a multiple wall structures, disposed at intervals along the substrate-surface of the substrate 101. Moreover, according to various other aspects, the primary stiffener 110 may be arranged symmetrically or asymmetrically in relation to a (reference) line of symmetry which may extend across a middle of the substrate 101.

Additionally, according to various aspects, the primary stiffener 110 may have a cross-sectional profile (e.g. a horizontal cross-sectional profile and/or a vertical cross-sectional profile) which may be, but is not limited to being, uniform.

FIG. 1B is a schematic diagram showing the primary stiffener of FIG. 1A detachably attached to an auxiliary stiffener, according to various aspects of the present disclosure.

FIG. 1C is a schematic diagram showing the auxiliary stiffener detached from the primary stiffener, according to various aspects of the present disclosure.

According to various aspects, the stiffener assembly 100 may include (e.g. optionally include) an auxiliary stiffener 120 configured to be attachable or mountable or connectable to the primary stiffener 110. The auxiliary stiffener 120 may serve or function as a “reinforcing arrangement” that enhances mechanical rigidity of the primary stiffener 110 on the substrate 101. The auxiliary stiffener 120 may include or may be a rigid body or structure. According to various aspects, the auxiliary stiffener 120 may include or may be made or composed of a same hard and/or rigid material as the primary stiffener 110. Alternatively, according to various other aspects, the auxiliary stiffener 120 may include or may be made of a different hard and/or rigid material from the primary stiffener 110.

According to various aspects, the auxiliary stiffener 120 may be connected to the primary stiffener 110 to reinforce the primary stiffener 110 and, in turn, the substrate 101 that the primary stiffener 110 may be disposed on or attached to. Specifically, the connection between the auxiliary stiffener 120 and the primary stiffener 110 may be a releasable connection.

For example, with reference to FIG. 1B, the primary stiffener 110 may include a first engagement arrangement 130. The first engagement arrangement 130 may be on or at an upper portion of the primary stiffener 110. The upper portion of the primary stiffener 110 may include an upper surface of the primary stiffener 110. Additionally, or alternatively, the aforementioned upper portion of the primary stiffener 110 may include one or more upper side surface(s) of the primary stiffener 110.

The auxiliary stiffener 120, on the other hand, may include a base portion. The base portion of the auxiliary stiffener 120 may be shaped and/or angled to correspond to a shape and/or an angle of the upper portion of the primary stiffener 110. Accordingly, the base portion of the auxiliary stiffener 120 may be configured to interface with the upper portion of the primary stiffener 110. The base portion of the auxiliary stiffener 120 may include a base surface of the auxiliary stiffener 120. Additionally, or alternatively, the aforementioned base portion of the auxiliary stiffener 120 may include one or more lower side surface(s) of the auxiliary stiffener 120. The auxiliary stiffener 120 may include a second engagement arrangement 140 on or at the base portion of the auxiliary stiffener 120, for detachable attachment (or releasable connection) with the first engagement arrangement 130 of the primary stiffener 110. Accordingly, when the base portion of the auxiliary stiffener 120 is stacked on and/or interfaced with the upper portion of the primary stiffener 110, the first engagement arrangement 130 of the primary stiffener 110 and the second engagement arrangement 140 of the auxiliary stiffener 120 may be engaged with each other to form a detachable joint.

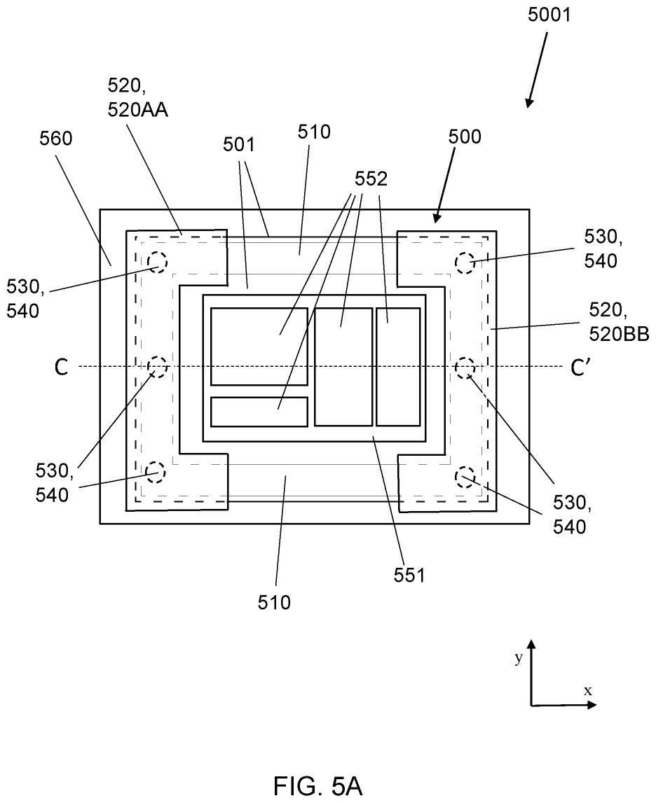

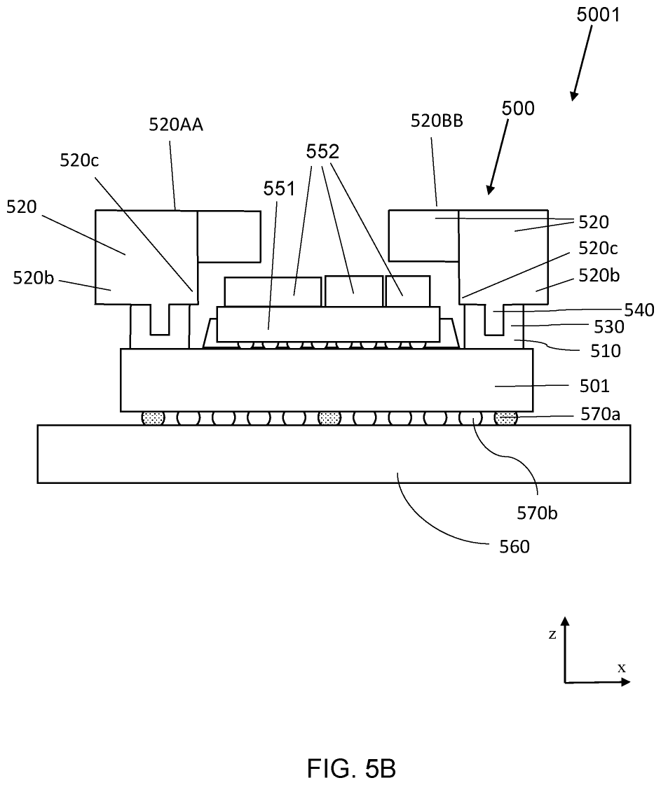

According to various other aspects, the auxiliary stiffener 120 may include a plurality of (e.g. two, three or more) auxiliary stiffener modules (see, for example, references “520AA” and “520BB” in FIG. 5A and FIG. 5B). In this configuration, each auxiliary stiffener module may be a modular sub-unit of the auxiliary stiffener 120. In other words, the plurality of auxiliary stiffener modules may collectively form the auxiliary stiffener 120 for reinforcing the primary stiffener 110. Furthermore, according to various other aspects, the plurality of auxiliary stiffener modules, of the auxiliary stiffener 120, may be discrete or individual or separate modules (or components) of the auxiliary stiffener 120. That is, the plurality of auxiliary stiffener modules may be non-integral with one another and may, thus, be selectively displaceable relative to one another (e.g. along the upper portion of the primary stiffener 110). According to various other aspects, the second engagement arrangement 140 of the auxiliary stiffener 120 may be distributed across the plurality of auxiliary stiffener modules. In particular, each auxiliary stiffener module may include a respective base portion configured to interface with the upper portion (e.g. a respective segment of the upper portion) of the primary stiffener 110. The base portion of each auxiliary stiffener module may constitute part of the base portion of the auxiliary stiffener. The second engagement arrangement 140 of the auxiliary stiffener 120 may be on or at (or distributed across or over) the base portions (e.g. base surfaces) of all of the plurality of auxiliary stiffener modules. Accordingly, each auxiliary stiffener module, of the plurality of auxiliary stiffener modules, may be detachably attached or releasably connected to a corresponding region or segment of the primary stiffener 110.

For ease of illustration, various aspects herein may be described or illustrated with reference to the auxiliary stiffener including or being a single or integral auxiliary stiffener. Nevertheless, aspects described or illustrated herein as such are not limited thereto. Thus, for example, aspects made with reference to the auxiliary stiffener including or being a single or integral auxiliary stiffener may be applicable to an auxiliary stiffener including or composed of a plurality of auxiliary stiffener modules, and vice versa.

According to various aspects, the first engagement arrangement 130 of the primary stiffener 110 may include or may be one or more snap-fit connectors on the upper portion (e.g. an upper surface) of the primary stiffener 110. The one or more snap-fit connectors may include or may be (i) one or more female snap-fit connectors recessed into (or from) the upper portion (e.g. the upper surface) of the primary stiffener 110, or (ii) one or more male snap-fit connectors protruding from the upper portion (e.g. the upper surface) of the primary stiffener 110. On the other hand, the auxiliary stiffener 120 may include the second engagement arrangement 140, which may include or may be corresponding snap-fit connectors (e.g. one or more female snap-fit connectors recessed into or from the base surface of the auxiliary stiffener 120, when the first engagement arrangement 130 includes or is one or more male snap-fit connectors). Accordingly, the first engagement arrangement 130 (e.g. one or more snap-fit connectors) of the primary stiffener 110 and the second engagement arrangement 140 (e.g. one or more corresponding snap-fit connectors) of the auxiliary stiffener 120 may be configured to engage with each other to form a detachable joint (e.g. releasable snap-fit joint) to detachably attach or releasably connect the auxiliary stiffener 120 to the primary stiffener 110.

As another example, according to various other aspects, the first engagement arrangement 130 of the primary stiffener 110 may include or may be one or more side surfaces of an upper portion of a wall structure of the primary stiffener 110. Additionally, the first engagement arrangement 130 of the primary stiffener 110 may include (e.g. optionally include) one or more indentations on the one or more side surfaces of the upper portion of the wall structure of the primary stiffener 110. On the other hand, the auxiliary stiffener 120 may include the second engagement arrangement 140, which may be a section of the auxiliary stiffener 120 that is configured (e.g. shaped) to straddle and/or clamp onto the aforementioned upper portion of the wall structure of the primary stiffener 110. Furthermore, the auxiliary stiffener 120 may releasably latch onto the one or more indentations on the one or more side surfaces of the upper portion of the wall structure of the primary stiffener 110. This configuration may enable the auxiliary stiffener 120 to be easily and detachably (e.g., releasably) attached (or removably mounted) to the primary stiffener 110.

Additional examples of the first engagement arrangement 130 of the primary stiffener 110 and the second engagement arrangement 140 of the auxiliary stiffener 120 may include a friction fit coupling arrangement, a pressure fit coupling arrangement, a magnetic coupling arrangement, a Velcro coupling arrangement, removable or temporary adhesive, a threaded coupling arrangement (e.g. screw threaded across the auxiliary stiffener 120 and the primary stiffener 110), snap button(s), etc. These various arrangements may enable the primary stiffener 110 and the auxiliary stiffener 120 to be detachably attached or releasably connected to each other.

According to various aspects of the present disclosure, a shape or an outline of the auxiliary stiffener 120 may correspond to (e.g. may be similar or identical to) a shape or an outline of the primary stiffener 110 (or a specific segment of the primary stiffener 110 to which the auxiliary stiffener 120 may be detachably attached or releasably connected). For instance, when the primary stiffener 110 takes the form of a circumferential (e.g. annular) structure, the auxiliary stiffener 120 may also be a corresponding circumferential (e.g. annular) structure. Similarly, if the primary stiffener 110 (or a specific segment thereof) is an elongate structure (e.g. a linear wall structure), the auxiliary stiffener 120 may adopt a corresponding elongate structure (e.g. a linear reinforcing structure).

According to various aspects, one or more dimensions and/or attributes (e.g. width, height, material, etc.) of the auxiliary stiffener 120 may be identical to, or may differ from, corresponding dimension(s) and/or attribute(s) of the primary stiffener 110. For example, a width (e.g. an average width, or uniform width) of the auxiliary stiffener 120 may be identical to, smaller than, or larger than a width (e.g. an average width, or uniform width) of the primary stiffener 110. Similarly, a height (e.g. an average height, or uniform height) of the auxiliary stiffener 120 may be identical to, smaller than, or larger than a height (e.g. an average height, or uniform height) of the primary stiffener 110. Additionally, the auxiliary stiffener 120 may be made or composed of a different material from the primary stiffener 110. For instance, the auxiliary stiffener 120 may be made or composed of a different metal or metal alloy from the primary stiffener 110, or the auxiliary stiffener 120 may be made or composed of carbon fibre while the primary stiffener 110 may be made or composed of steel (e.g. stainless steel), etc.

These aspects allow for customization or tailoring of the auxiliary stiffener 120 (i.e. the reinforcing arrangement for the primary stiffener 110) for fulfilling various requirements for minimizing or preventing deformation in the primary stiffener 110 and, consequently, in the substrate 101 of the semiconductor assembly 1001 to which the primary stiffener 110 may be applied or attached.

Furthermore, a weight of the auxiliary stiffener 120 may be the same as, lighter than, or heavier than a weight of the primary stiffener 110. According to various aspects, when a heavy or relatively heavier auxiliary stiffener 120 is stacked over the primary stiffener 110, the heavy auxiliary stiffener 120 may exert downward pressure on the primary stiffener 110, thereby contributing to its detachable or releasable attachment to the primary stiffener 110. Hence, a weight of the auxiliary stiffener 120 may constitute at least a component of the second engagement arrangement 140 of the auxiliary stiffener 120, according to various aspects.

In various aspects, with reference to FIG. 1A and FIG. 1C, when the primary stiffener 110 is attached to the substrate 101 (e.g. a semiconductor package substrate) of the semiconductor assembly 1001 (e.g. a semiconductor package), a height of the primary stiffener 110 relative to the substrate-surface of the substrate 101 may not exceed (in other words, may not be taller than) a tallest point of one or more semiconductor devices 180 (e.g. which may include one or more dies) on the substrate-surface of the substrate 101. In order to enhance the mechanical support provided by such a (short) primary stiffener 110, a size (e.g. height and/or width) of the primary stiffener 110 may be effectively augmented or “extended” by attaching the auxiliary stiffener 120 (i.e. the reinforcing arrangement) to it.

Moreover, the detachable nature of the auxiliary stiffener 120, according to the various aspects, may allow selective utilization when (e.g. only when) external forces and/or heat are acting on the semiconductor assembly 1001, for example, during processes, such as surface mount or reflow processes. The auxiliary stiffener 120 can be detached when no longer required. This detachment capability may prevent an end product of the semiconductor assembly 1001 from unnecessarily increasing in height or thickness. The resulting height or thickness of the end product of the semiconductor assembly 1001 may instead correspond to a height or thickness of the (short) primary stiffener 110 or to the tallest point of the one or more semiconductor devices 180 (or dies) on the substrate 101. In other words, the end product of the semiconductor assembly 1001, according to the various aspects, may maintain a thin or relatively thin profile.

Accordingly, the primary stiffener 110, equipped with the first engagement arrangement 130 configured to detachably join or attach the auxiliary stiffener 120 to it, may facilitate production of relatively thin semiconductor assemblies 1001, even when subjected to substantial stresses and/or heat during the manufacturing process.

According to various aspects, the substrate 101 and the primary stiffener 110, with the base surface of the primary stiffener 110 attached or affixed to the substrate-surface of the substrate 101, may collectively form or be part of the semiconductor assembly 1001.

According to various other aspects, the semiconductor assembly 1001 may include (e.g. optionally include) the auxiliary stiffener 120. The auxiliary stiffener 120 may (e.g. optionally) be detachably attached or releasably connected to the primary stiffener 110, to reinforce the primary stiffener 110, within the semiconductor assembly 1001.

According to various aspects, the semiconductor assembly 1001 may include (e.g. further include) one or more semiconductor devices 180 on the substrate-surface of the substrate 101. The one or more semiconductor devices 180 may include, but is not limited to, one or more dies (e.g. stacked dies and/or adjacent dies), integrated circuit(s), chip(s), etc.

According to various aspects, a height or thickness of the primary stiffener 110 may not exceed a height or thickness of the one or more semiconductor devices 180 (or the one or more dies of the semiconductor devices 180), relative to the substrate-surface of the substrate 101. For example, a height of the primary stiffener 110 may be equal to or may be shorter than a height or a tallest point of the one or more semiconductor devices 180 (or the one or more dies of the semiconductor devices 180).

According to various aspects, when the height of the primary stiffener 110 is shorter than a height or a tallest point of the one or more semiconductor devices 180 (or the one or more dies of the semiconductor devices 180), and with the auxiliary stiffener 120 removed from the semiconductor assembly 1001, a heat spreader that is placed over and onto the one or more semiconductor devices 180 (e.g. onto a topmost surface of the one or more semiconductor devices 180 or the dies) may not be contacting the (shorter) primary stiffener 110, thereby ensuring clearance between the heat spreader and the primary stiffener 110 to maximize heat transfer efficiency.

According to various aspects, the semiconductor assembly 1001 may include (e.g. optionally include) the heat spreader engaged with the one the one or more semiconductor devices 180 (or the one or more dies of the semiconductor devices 180), with the auxiliary stiffener 120 removed (or not present) within the semiconductor assembly 1001.

According to various aspects, the semiconductor assembly 1001 may include (e.g. further include) a circuit board 160 (e.g. a motherboard). The substrate 101 may be stacked over or on the circuit board 160 and may be connected to the circuit board 160 via a first interconnect member 170a and a second interconnect member 170b, with the first interconnect member 170a and the second interconnect member 170b between the circuit board 160 and the substrate 101. The first interconnect member 170a may include or may be made of a first material, and the second interconnect member 170b may include or may be made of a second material. According to various aspects, the first material may be harder or more rigid than the second material. According to various aspects, at least the second material (or each of the first material and the second material) may include or may be an electrically conductive material. Accordingly, the first interconnect member 170a, made of a harder or more rigid material, may be strategically placed on the circuit board 160 to prevent squash or deformation (e.g. of the substrate 101, the circuit board 160, and the second interconnect member 170b), while the second interconnect member 170b, made of a softer material, may effectively facilitate electrical connectivity.

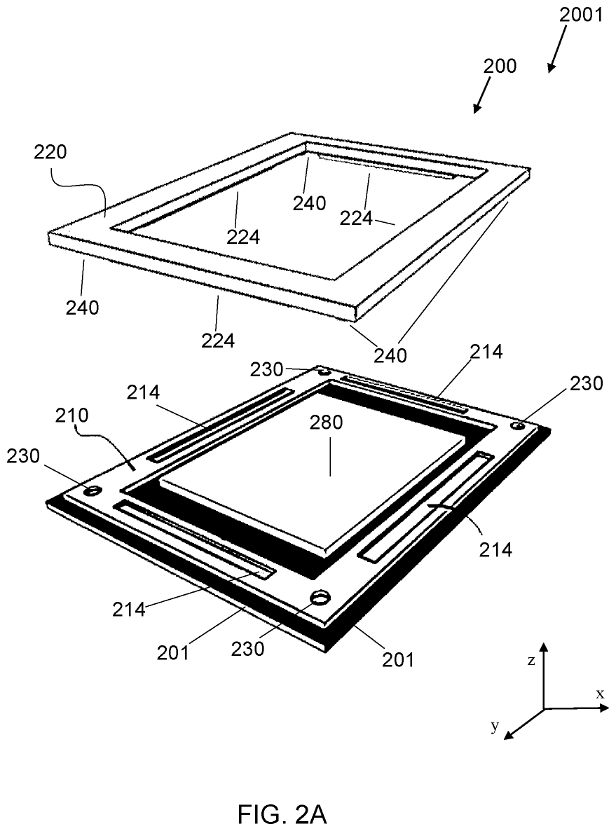

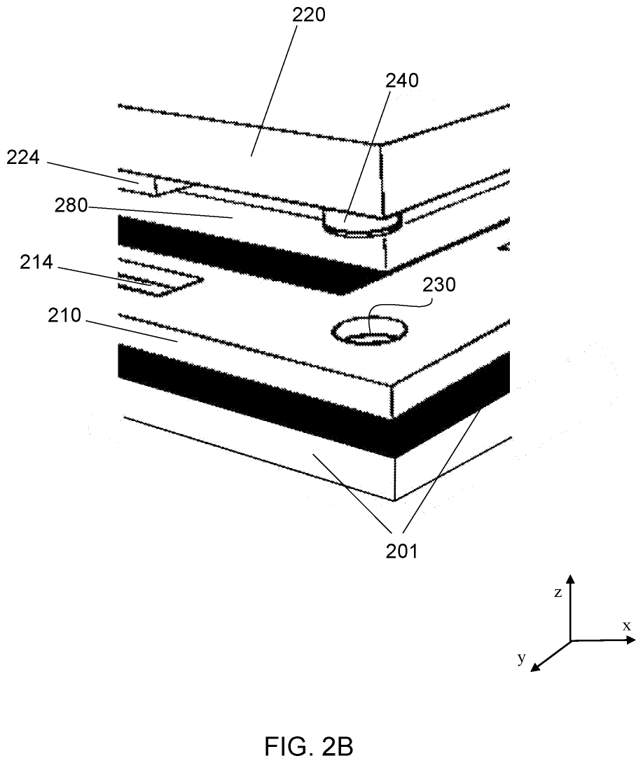

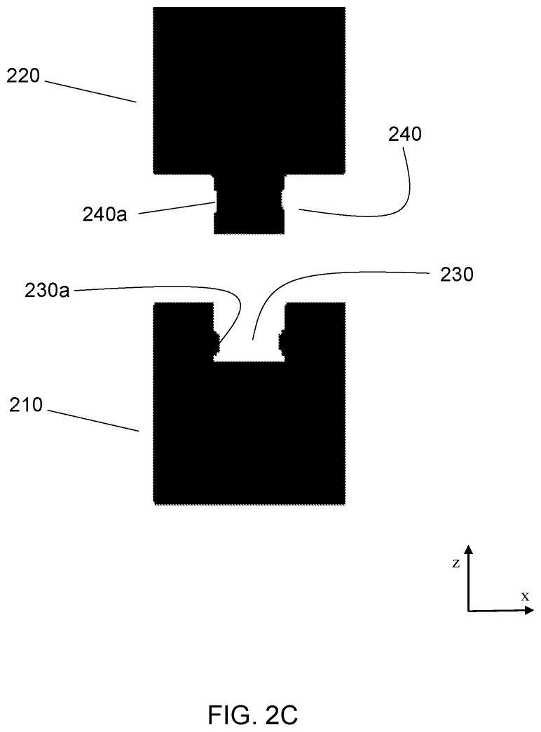

FIG. 2A is a perspective view of a primary stiffener attached to a peripheral region of a substrate of a stiffener assembly and an auxiliary stiffener detached from the primary stiffener, according to various aspects of the present disclosure.

FIG. 2B is a close-up perspective view of a female snap-fit connector of a first engagement arrangement of the primary stiffener and a male-snap-fit connector of a second engagement arrangement of the auxiliary stiffener, according to various aspects of the present disclosure.

According to various aspects, there may be provided the stiffener assembly 200. According to various aspects, the stiffener assembly 200 may contain any one or more or all the features and/or limitations of the stiffener assembly 100 of FIG. 1A to FIG. 1C. In the following, the stiffener assembly 200 is described with like reference characters generally referring to the same or corresponding parts/features of the stiffener assembly 100 of FIG. 1A to FIG. 1C. The description of the parts/features made with respect to the stiffener assembly 200 may also be applicable with respect to the stiffener assembly 100, and vice versa.

As in the stiffener assembly 100 of FIG. 1A to FIG. 1C, the stiffener assembly 200 may include a primary stiffener 210. Further, the stiffener assembly 200 may include (e.g. optionally include) an auxiliary stiffener 220.

As shown, the primary stiffener 210 may include a base surface that is attached to an upper surface (i.e. “substrate-surface”) of a substrate 201 (e.g. a package substrate). According to various aspects, the primary stiffener 210 may be affixed (e.g. via a permanent adhesive) to the substrate-surface of the substrate 201.

The primary stiffener 210 may include an upper surface, i.e. opposite its base surface. The upper surface of the primary stiffener 210 may be, but is not limited to being, parallel (e.g. substantially parallel) with its base surface. According to various aspects, the upper surface of the primary stiffener 210 may include a first engagement arrangement 230. The first engagement arrangement 230 may include at least one detachable connector configured to engage with a corresponding detachable connector of a second engagement arrangement 240 at a base surface of the auxiliary stiffener 220, to form a detachable or a releasable joint between the primary stiffener 210 and the auxiliary stiffener 220.

FIG. 2C is a cross-sectional profile of the female snap-fit connector of the first engagement arrangement of the primary stiffener and the male snap-fit connector of the second engagement arrangement of the auxiliary stiffener, according to various aspects of the present disclosure.

As an example, shown in FIG. 2C, the detachable connector of the first engagement arrangement 230 of the primary stiffener 210 may be or may include at least one female snap-fit connector recessed into (or from) the upper surface of the primary stiffener 210. The corresponding detachable connector of the second engagement arrangement 240 of the auxiliary stiffener 220 may be or may include a male snap-fit connector protruding from the base surface of the auxiliary stiffener 220. As shown, the male snap-fit connector may include a general “T”-shaped profile and may include (e.g. further include) a recess or groove 240a on or around a side surface thereof. The female snap-fit connector may include a general “U”-shaped profile and may include (e.g. further include) a protrusion or rim 230a protruding from and/or extending around a side surface thereof for being received by the recess or groove 240a at the side surface of the male snap-fit connector (i.e. when the first engagement arrangement 230 and the second engagement arrangement 240 are engaged with each other). According to various aspects, the protrusion or rim 230a of the female snap-fit connector may have a rounded surface (in other words, without or free from any sharp or pointed edges), to facilitate insertion as well as detachment (or removal) of the male snap-fit connector.

According to various aspects, the female snap-fit connector(s) and the male snap-fit connector(s) may be manufactured using any suitable process, such as cold/hot rolling. In cold/hot rolling, a piece of material, such as metal, may be passed between a grooved/slotted or slot-forming roller, on one side, and a smooth roller (i.e. without any grooves or slots), on the opposite side, to shape the material. Additionally, punching or stamping processes, for example, using a puncher or stamp, may also be employed.

Referring back to FIG. 2A, according to various aspects, the primary stiffener 210 may include at least two neighboring or adjacent, non-parallel linear walls (or wall structures) adjoining each other at an angle to form (or that forms) a corner region (or corner) of the primary stiffener 210. As shown, these linear walls may meet at an angle, such as a perpendicular or substantially perpendicular angle. The primary stiffener 210, as shown in FIG. 2A, may include four linear walls adjoining one another, in an end-to-end arrangement to form a circumferential structure around a central opening or space. Each pair of neighboring and adjoined linear walls, within the set of four linear walls, may meet at a respective corner region of the primary stiffener 210. Consequently, this configuration with the set of four linear walls may give rise to four corner regions within the primary stiffener 210.

According to various other aspects (not shown), the primary stiffener 210 may include any other plural number (e.g. three, five or more) of walls (e.g. linear walls), with these walls adjoined in an end-to-end arrangement to surround a central opening or space. In such a configuration, the primary stiffener 210 may have a corresponding number of corner regions that matches the number of walls.

As shown in FIG. 2A, the first engagement arrangement 230 (or at least a portion or a sub-arrangement of the first engagement arrangement 230) of the primary stiffener 210 may be positioned or disposed at the corner region (or at each corner region) of the primary stiffener 210. Specifically, the at least one detachable connector (e.g. snap-fit connector(s)) of the first engagement arrangement 230 of the primary stiffener 210 may be positioned or disposed at the corner region (or at each corner region) of the primary stiffener 210. According to various other aspects (not shown), the first engagement arrangement 230 of the primary stiffener 210 may be disposed along a linear segment of a wall of the primary stiffener 210. The linear segment of the wall of the primary stiffener 210 may be connecting (or may be between) a pair of corner regions of the primary stiffener 210.

According to various aspects, the auxiliary stiffener 220 may have a general shape or outline that corresponds to that of the primary stiffener 210. For example, as shown, the auxiliary stiffener 220 may include at least two neighboring or adjacent, non-parallel linear walls adjoining at a corner region of the auxiliary stiffener 220. Specifically, the auxiliary stiffener 220, as shown in FIG. 2A, may include four linear walls adjoining one another, in an end-to-end arrangement to form a circumferential structure around a central opening or space. Each pair of neighboring and adjoined linear walls, within the set of four linear walls, of the auxiliary stiffener 220 may be at right angles (in other words, perpendicular or substantially perpendicular) to each other and may meet at a respective corner region of the auxiliary stiffener 220. Consequently, the auxiliary stiffener 220 may have four corner regions.

According to various other aspects (not shown), the auxiliary stiffener 220 may include any other plural number (e.g. three, five or more) of walls (e.g. linear walls), with these walls adjoined in an end-to-end arrangement to surround a central opening or space. In such a configuration, the auxiliary stiffener 220 may have a corresponding number of corner regions that matches the number of walls (e.g. linear walls).

As shown in FIG. 2A, the second engagement arrangement 240 (or at least a portion or a sub-arrangement of the second engagement arrangement 240) of the auxiliary stiffener 220 may be positioned or disposed at the corner region (or at each corner region) of the auxiliary stiffener 220. Specifically, the at least one corresponding detachable connector (e.g. corresponding snap-fit connector) of the second engagement arrangement 240 of the auxiliary stiffener 220 may be positioned or disposed at the corner region (or at each corner region) of the auxiliary stiffener 220. According to various other aspects (not shown), the second engagement arrangement 240 of the auxiliary stiffener 220 may be disposed along a linear segment of a wall of the auxiliary stiffener 220. The linear segment of the wall of the auxiliary stiffener 220 may be connecting (or may be between) a pair of corner regions of the auxiliary stiffener 220.

Accordingly, the corner regions of the primary stiffener 210 may be mechanically latched or attached (i.e. detachably attached or releasably connected) to the corner regions of the auxiliary stiffener 220 to reinforce the corner regions of the primary stiffener 210. Through this arrangement, the corner regions the of the primary stiffener 210 may maintain contact with and/or remain secured to the auxiliary stiffener 220 (i.e. acting as the “reinforcing arrangement”), even under the impact of external forces and/or heat during processes, such as surface mount or reflow processes. The auxiliary stiffener 220 may, thus, reinforce the primary stiffener 210 against potential deformation (e.g. warpage) that commonly occurs at the corner regions of a “stiffener” structure.

Referring to FIG. 2A and FIG. 2B, according to various aspects, the primary stiffener 210 may include (further include) at least one alignment element 214 at an upper surface of the primary stiffener 210. Furthermore, the auxiliary stiffener 220 may include at least one corresponding alignment element 224 at the base surface of the auxiliary stiffener 220 configured to align and/or mate with the aforementioned at least one alignment element 214 of the primary stiffener 210. FIG. 2A shows the primary stiffener 210 having a plurality of (e.g. four) alignment elements 214, while the auxiliary stiffener 220 may have a corresponding plurality of (e.g. four) alignment elements 224.

As an example, referring to FIG. 2B, the alignment element 214 of the primary stiffener 210 may include or may be a recess (e.g. opening, slot, etc.) into the upper surface of the primary stiffener 210. Correspondingly, the alignment element 224 of the auxiliary stiffener 220 may include or may be a protrusion (e.g. an elongated protrusion) extending from the base surface of the of the auxiliary stiffener 220. The protrusion may be slidably inserted into the recess. According to various other aspects (not shown), the alignment element 214 of the primary stiffener 210 may be a hole (e.g. through-hole, or blind-hole, circular hole, or squarish hole, etc.), while the alignment element 224 of the auxiliary stiffener 220 may be a protrusion (e.g. a pin) configured (e.g. shaped) for insertion into the hole.

According to various aspects, the alignment element 214 of the primary stiffener 210 and the alignment element 224 of the auxiliary stiffener 220 may be configured for slidable engagement along an insertion axis. As a result, the alignment element 214 of the primary stiffener 210 and the alignment element 224 of the auxiliary stiffener 220 may facilitate (e.g. guide) the attachment and detachment of the auxiliary stiffener 220 relative to the primary stiffener 210 along this insertion axis. In accordance with various aspects, the insertion axis maybe a linear reference axis that is perpendicular (e.g. substantially perpendicular) to the base surface and/or upper surface of the primary stiffener 210.

Referring to FIG. 2A, according to various aspects, the at least one detachable connector of the first engagement arrangement 230 and the at least one alignment element 214, of the primary stiffener 210, may be arranged in an alternating manner with respect to one another (e.g. on the upper surface of the primary stiffener 210). Correspondingly, the at least one detachable connector of the second engagement arrangement 240 and the at least one alignment element 224, of the auxiliary stiffener 220, may be arranged in an alternating manner with respect to one another (e.g. on the base surface of the auxiliary stiffener 220). Accordingly, according to various aspects, a plurality of detachable connectors of the first engagement arrangement 230 of the primary stiffener 210 may be spaced apart from one another (e.g. on the upper surface of the primary stiffener 210), while a plurality of detachable connectors of the second engagement arrangement 240 of the auxiliary stiffener 220 may be spaced apart from one another (e.g. on the base surface of the auxiliary stiffener 220). Furthermore, according to various aspects, a plurality of alignment elements 214 of the primary stiffener 210 may be spaced apart from one another (e.g. on the upper surface of the primary stiffener 210), while a plurality of alignment elements 224 of the auxiliary stiffener 220 may be spaced apart from one another (e.g. on the base surface of the auxiliary stiffener 220). According to various aspects, the aforementioned spacing(s) may occur at regular or non-regular intervals.

According to various aspects, with reference to FIG. 2A, the substrate 201 and the stiffener assembly 200 (e.g. at least the primary stiffener 210 of the stiffener assembly 200), may collectively form or be part of a semiconductor assembly 2001.

The semiconductor assembly 2001 may include (e.g. further include) a semiconductor device 280 (e.g. which may include a die) on the substrate-surface of the substrate 201. As shown, the semiconductor device 280 may be within the central opening or space that is surrounded by, at least, the primary stiffener 210 of the stiffener assembly 200.

According to various aspects, a height (or thickness) of the semiconductor device 280 (or the die) relative to the substrate-surface of the substrate 201 may be taller than a height (or thickness) of the primary stiffener 210 relative to the substrate-surface of the substrate 201.

According to various aspects, the semiconductor assembly 2001 may include (e.g. optionally include) the auxiliary stiffener 220 detachably attached to the primary stiffener 210.

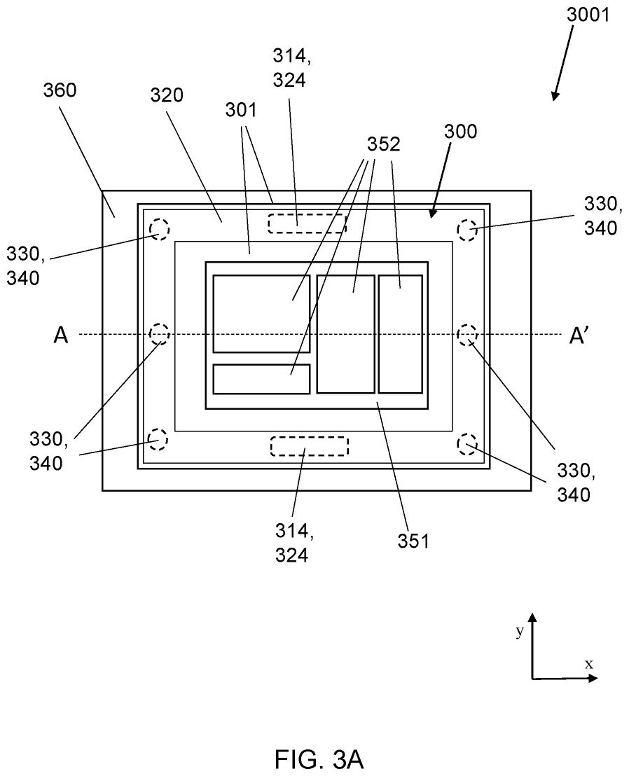

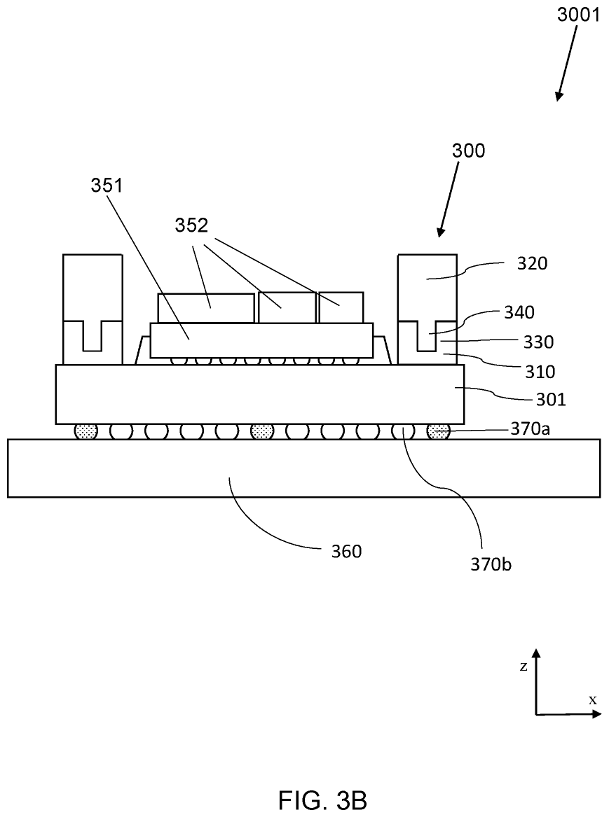

FIG. 3A shows a schematic top view of a stiffener assembly with a primary stiffener and a first variant auxiliary stiffener, within a semiconductor assembly, according to various aspects of the present disclosure.

FIG. 3B is a side view of FIG. 3A taken along line A-A, according to various aspects of the present disclosure.

According to various aspects, there may be provided the stiffener assembly 300.

According to various aspects, the stiffener assembly 300 may contain any one or more or all the features and/or limitations of the stiffener assembly 100 of FIG. 1A to FIG. 1C and/or the stiffener assembly 200 of FIG. 2A and FIG. 2B. In the following, the stiffener assembly 300 is described with like reference characters generally referring to the same or corresponding parts/features of the stiffener assembly 100 of FIG. 1A to FIG. 1C and/or the stiffener assembly 200 of FIG. 2A and FIG. 2B. The description of the parts/features made with respect to the stiffener assembly 300 may also be applicable with respect to the stiffener assembly 100 and/or the stiffener assembly 200, and vice versa.

Referring to FIG. 3B, the stiffener assembly 300 may include a primary stiffener 310. As shown, the primary stiffener 310 may be disposed on a substrate 301 (e.g. a package substrate) to provide mechanical support to the substrate 301.

The stiffener assembly 300 may further include an auxiliary stiffener 320 (i.e. first variant auxiliary stiffener 320) detachably attachable (or attached) to the primary stiffener 310 for reinforcing the primary stiffener 310.

One or more dimensions (e.g. height, width, etc.) of the first variant auxiliary stiffener 320 may be scalable or configurable based on warpage prevention requirements of the primary stiffener 310 and, in turn, of the substrate that the primary stiffener 310 may be disposed on. For instance, with reference to FIG. 3B, according to various aspects, a height (or largest height or thickness) of the first variant auxiliary stiffener 320 may be larger or taller than a height (or largest height or thickness) of the primary stiffener 310 (i.e. measured along a direction perpendicular to a base surface of each stiffener 310, 320, e.g. along the z-axis). On the other hand, a width of the first variant auxiliary stiffener 320 (i.e. measured along a direction parallel with a base surface of the auxiliary stiffener 320, e.g. along the x-axis or the y-axis depending on an orientation of the width being measured) may be similar or equal to a width of the primary stiffener 310 (i.e. measured along a direction parallel with a base surface of the primary stiffener 310, e.g. along the x-axis or the y-axis).

Furthermore, a general shape of the first variant auxiliary stiffener 320 may be similar or identical to a general shape of the primary stiffener 310. As an example, shown in FIG. 3A, both the primary stiffener 310 (i.e. underneath the first variant auxiliary stiffener 320) and the first variant auxiliary stiffener 320 may have a same number of adjoining peripheral walls surrounding a respective central opening or space (e.g. a through-hole opening). Specifically, both the primary stiffener 310 and the first variant auxiliary stiffener 320 may be squarish or rectangular-shaped circumferential structures surrounding a respective central opening or space.

According to various aspects, the first variant auxiliary stiffener 320 may be detached from the primary stiffener 310 when no longer required (e.g. after a surface mount or reflow process has been performed on the substrate 301). Subsequently, the first variant auxiliary stiffener 320 may be detachably attached to another primary stiffener 310 having the first engagement arrangement 330 (i.e. that is configured to be detachably engaged with the second engagement arrangement 340 of the first variant auxiliary stiffener 320). Accordingly, the stiffener assembly 300, according to the various aspects, may offer a reusable auxiliary stiffener 320.

According to various aspects, with reference to FIG. 3A, the primary stiffener 310 may include (e.g. optionally include) at least one alignment element 314 at an upper surface of the primary stiffener 310, while the first variant auxiliary stiffener 320 may include at least one corresponding alignment element 324 on the base surface of the first variant auxiliary stiffener 320. The at least one alignment element 314 and the at least one corresponding alignment element 324 may be configured (e.g. shaped) to mate with each other for aligning (e.g. precise alignment) and positioning of the first variant auxiliary stiffener 320 relative to the primary stiffener 310.

According to various aspects, the substrate 301 and the stiffener assembly 300 (e.g. at least the primary stiffener 310 of the stiffener assembly 300), may collectively form or be part of a semiconductor assembly 3001.

As a non-limiting example, as shown in FIG. 3A and FIG. 3B, the primary stiffener 310 may be a circumferential structure, that extends along the substrate-surface of the substrate 301, over a peripheral region of the substrate 301. More specifically, the primary stiffener 310 may include a plurality of walls, adjoined end-to-end to surround a central space, on the substrate-surface of the substrate 301.

The semiconductor assembly 3001 may include (e.g. further include) one or more semiconductor devices (e.g. which may include dies) within the central space on the substrate-surface of the substrate 301. As a non-limiting example, shown in FIG. 3A and FIG. 3B, the one or more semiconductor devices may include at least one “base die 351” disposed on the substrate-surface of the substrate 301 and at least one “other die” (e.g. three other dies 352) disposed on or stacked on the base die 351 itself.

According to various aspects, a tallest or furthest point (e.g. relative to the substrate-surface of the substrate 301) of the one or more semiconductor devices on the substrate-surface (e.g. the topmost surface of the one other die 352, i.e. that is stacked on the base die 351) may be further away from the substrate-surface than an upper (or topmost) surface of the primary stiffener 310 from the substrate-surface. Thus, with the first variant auxiliary stiffener 320 detached from the primary stiffener 310, the primary stiffener 310 may not interfere nor come into contact with a heat spreader (e.g. a substantially flat surface of the heat spreader) that is placed on the one or more semiconductor devices (or on at least the topmost surface of the one other die 352).

According to various aspects, with reference to FIG. 3B, the semiconductor assembly 3001 may include (e.g. further include) a circuit board 360 (e.g. a main circuit board, motherboard, printed circuit board, etc.). The substrate 301 may be disposed over the circuit board 360 and may be connected to the circuit board 360 via a first interconnect member 370a and a second interconnect member 370b, with the first interconnect member 370a and the second interconnect member 370b sandwiched between the circuit board 360 and the substrate 301. The first interconnect member 370a may include or may be made or composed of a first material (or material composition, e.g. an alloy), and the second interconnect member 370b may include or may be made or composed of a second material (or material composition). According to various aspects, the first material (or material composition) may be harder than the second material (or material composition). According to various aspects, at least the second material (or each of the first material and the second material) may include or may be an electrically conductive material. Accordingly, the first interconnect member 370a, made of a harder material, may be strategically placed on the circuit board 360 to prevent squash or deformation (e.g. of the substrate 301, the circuit board 360, as well as the second interconnect member 370b). As an example, shown in FIG. 3B, the first interconnect member 370a may include or may be at least one solder ball (e.g. of a Ball Grid Array (“BGA”)), and the second interconnect member 370b may include or may be at least one other solder ball (e.g. of another BGA). The at least one solder ball of the first interconnect member 370a may be positioned below (e.g. directly below), in other words, may be aligned (e.g. vertically aligned) with, the primary stiffener 310. For example, the at least one solder ball of the first interconnect member 370a may be disposed or distributed around and/or along a peripheral region of the substrate at its base surface, opposite the substrate-surface of the substrate 301. Specifically, at least one solder ball of the first interconnect member 370a may be disposed, at least, below the first engagement arrangement 330 (e.g. below each detachable connector of the first engagement arrangement 330). As a further example, at least one solder ball of the first interconnect member 370a may be (e.g. additionally, or alternatively) disposed below (in other words, opposite) the central space (i.e. where one or more dies 351, 352 may be disposed). In this manner, the harder first interconnect member 370a may prevent squash (e.g. “BGA squash”), particularly, at a point of time when the first variant auxiliary stiffener 320 is being detachably attached onto (or against) the primary stiffener 310 and/or during a mounting process, surface mount process, reflow process, etc.

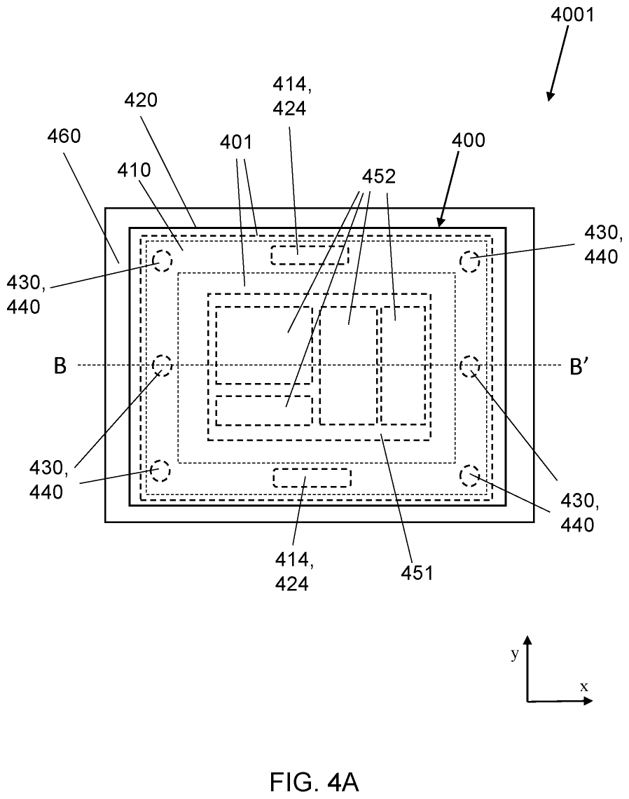

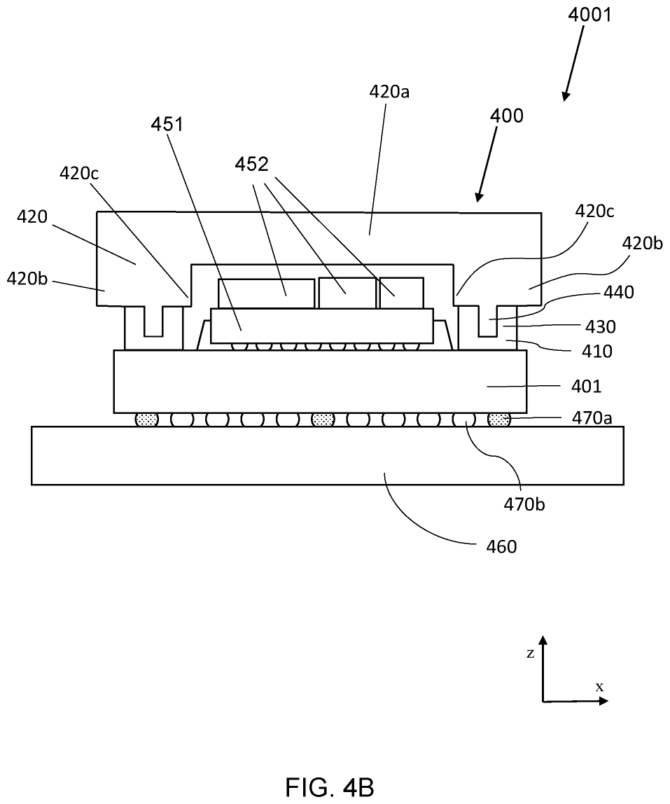

FIG. 4A shows a schematic top view of a stiffener assembly with a primary stiffener and a second variant auxiliary stiffener, within a semiconductor assembly, according to various aspects of the present disclosure.

FIG. 4B is a side view of FIG. 4A taken along line B-B′, according to various aspects of the present disclosure.

According to various aspects, there may be provided the stiffener assembly 400.

According to various aspects, the stiffener assembly 400 may contain any one or more or all the features and/or limitations of the stiffener assembly 100 of FIG. 1A to FIG. 1C and/or the stiffener assembly 200 of FIG. 2A and FIG. 2B. In the following, the stiffener assembly 400 is described with like reference characters generally referring to the same or corresponding parts/features of the stiffener assembly 100 of FIG. 1A to FIG. 1C and/or the stiffener assembly 200 of FIG. 2A and FIG. 2B. The description of the parts/features made with respect to the stiffener assembly 400 may also be applicable with respect to the stiffener assembly 100 and/or the stiffener assembly 200, and vice versa.

Referring to FIG. 4B, the stiffener assembly 400 may include a primary stiffener 410. As shown, the primary stiffener 410 may be disposed on a substrate 401 (e.g. a package substrate) to provide mechanical support to the substrate 401.

The stiffener assembly 400 may include (e.g. optionally include) an auxiliary stiffener 420 (i.e. second variant auxiliary stiffener 420) detachably attachable (or attached) to the primary stiffener 410 for reinforcing the primary stiffener 410.

One or more dimensions (e.g. size, height, width, etc.) of the second variant auxiliary stiffener 420 may be scalable or configurable based on warpage prevention requirements to the primary stiffener 410 and, in turn, of the substrate 401 that the primary stiffener 410 may be disposed on. For instance, with reference to FIG. 4B, according to various aspects, an overall (or largest) height or thickness of the second variant auxiliary stiffener 420 may be larger or taller than a height or thickness of the primary stiffener 410 (i.e. measured along a direction perpendicular to a base surface of each stiffener 410, 420, e.g. along the z-axis). Further, a width of walls (e.g. side walls) of the second variant auxiliary stiffener 420 may be larger than a width of walls of the primary stiffener 410 (i.e. measured along a direction parallel with a base surface of each stiffener 410, 420, e.g. along the x-axis or the y-axis depending on an orientation of the width being measured). In particular, when the second variant auxiliary stiffener 420 is detachably attached to the primary stiffener 410, with the walls of the auxiliary stiffener 420 stacked on or over the walls of the primary stiffener 410, an outer side portion 420b (at an outer wall surface) of the auxiliary stiffener 420 may be cantilevered or extending sideways or protruding outwards away from an outer wall surface of the primary stiffener 410. Furthermore, an inner side portion 420c (at an inner wall surface) of the auxiliary stiffener 420 may be cantilevered or extending sideways or extending inwards of the stiffener assembly 400, away from an inner wall surface of the primary stiffener 410.

Additionally, as shown, the second variant auxiliary stiffener 420 may have a different form or geometry from the primary stiffener 410. In particular, with reference to FIG. 4A and FIG. 4B, while the primary stiffener 410 may have a plurality of adjoining walls surrounding and defining a central opening that is a through-hole opening, the auxiliary stiffener 420 may take on a “closed-roof” configuration. As shown in FIG. 4B, a roof segment (or roof portion) 420a of the auxiliary stiffener 420 may have a planar or substantially planar form and may be extending across the (upright) walls of the auxiliary stiffener 420. An underside of the roof segment 420a may be recessed, creating or define an inner space or cavity. Particularly, the underside of the roof segment 420a, along with the inner wall surfaces of both the primary stiffener 410 and the auxiliary stiffener 420, as well as the substrate-surface of the substrate 401, may collectively form or define an enclosure for one or more semiconductor devices (or dies 451, 452).

According to various aspects, the second variant auxiliary stiffener 420 may be detached or removed from the primary stiffener 410 when no longer required. Subsequently, it may be detachably attached or releasably connected to another primary stiffener 410 having the first engagement arrangement 430 (i.e. that is configured to be detachably attachable to or with the second engagement arrangement 440 of the second variant auxiliary stiffener 420). Accordingly, the stiffener assembly 400, according to the various aspects, may offer a reusable auxiliary stiffener 420.

According to various aspects, with reference to FIG. 4A, the primary stiffener 410 may include (e.g. optionally include) at least one alignment element 414 at an upper surface of the primary stiffener 410, while the second variant auxiliary stiffener 420 may include at least one corresponding alignment element 424 on the base surface of the second variant auxiliary stiffener 420. The at least one alignment element 414 and the at least one corresponding alignment element 424 may be configured to mate with each other for aligning the second variant auxiliary stiffener 420 relative to the primary stiffener 410.

According to various aspects, the substrate 401 and the stiffener assembly 400 (e.g. at least the primary stiffener 410 of the stiffener assembly 400), may collectively form or be part of a semiconductor assembly 4001.

As shown, the primary stiffener 410 may be a circumferential structure, on the substrate-surface, across a peripheral region of the substrate 401. More specifically, the primary stiffener 410 may include a plurality of (e.g. four) adjoining walls, adjoined end-to-end to surround a central space, on the substrate-surface of the substrate 401.

The semiconductor assembly 4001 may include (e.g. further include) one or more semiconductor devices (e.g. which may include dies) within the central space on the substrate-surface of the substrate 401. As a non-limiting example, shown in FIG. 4B, the one or more semiconductor devices may include at least one base die 451 disposed on the substrate-surface and at least one other die (e.g. three other dies 452) disposed on or stacked on the base die 451.

A tallest point (e.g. relative to the substrate-surface of the substrate 401) of the one or more semiconductor devices on the substrate-surface (e.g. the topmost surface of the one other die 452, i.e. that is stacked on the base die 451) may be further away from the substrate-surface of the substrate 401 than an upper (or topmost) surface of the primary stiffener 410. Thus, when the second variant auxiliary stiffener 420 is detached from the primary stiffener 410, the primary stiffener 410 may not interfere nor come into contact with a heat spreader (e.g. substantially flat heat spreader) that may be subsequently placed on the one or more semiconductor devices (or on at least the topmost surface of the one other die 452).

According to various aspects, with reference to FIG. 4B, the semiconductor assembly 4001 may include (e.g. further include) a circuit board 460 (e.g. a main circuit board, motherboard, printed circuit board, etc.). The substrate 401 may be disposed over the circuit board 460 and may be connected to the circuit board 460 via a first interconnect member 470a and a second interconnect member 470b, with the first interconnect member 470a and the second interconnect member 470b sandwiched between the circuit board 460 and the substrate 401. The first interconnect member 470a may include or may be made of a first material (or material composition, e.g. an alloy), and the second interconnect member 470b may include or may be made of a second material (or material composition). According to various aspects, the first material (or material composition) may be harder than the second material (or material composition). According to various aspects, at least the second material (or each of the first material and the second material) may include or may be an electrically conductive material. Accordingly, the first interconnect member 470a, made of a harder material, may be strategically placed on the circuit board 460 to prevent squash or deformation (e.g. of the substrate 401, the circuit board 460, and the second interconnect member 470b). As an example, shown in FIG. 4B, the first interconnect member 470a may include or may be at least one solder ball (e.g. of a BGA), and the second interconnect member 470b may include or may be at least one other solder ball (e.g. of another BGA). The at least one solder ball of the first interconnect member 470a may be positioned below (e.g. directly below), in other words, may be aligned (e.g. vertically aligned) with, the primary stiffener 410. For example, the at least one solder ball of the first interconnect member 470a may be disposed or distributed around a peripheral region of the substrate 401 at its base surface, opposite the substrate-surface of the substrate 401. Specifically, at least one solder ball of the first interconnect member 470a may be disposed, at least, below the first engagement arrangement 430 (e.g. below each detachable connector of the first engagement arrangement 430). As a further example, at least one solder ball of the first interconnect member 470a may be disposed below (in other words, opposite) the central space (i.e. where one or more dies 451, 452 may be disposed). In this manner, the harder first interconnect member 470a may prevent squash when the second auxiliary stiffener 420 is detachably attached onto the primary stiffener 410 and/or during a mounting process, surface mount process, reflow process, etc.

FIG. 5A shows a schematic top view of a stiffener assembly with a primary stiffener and a third variant auxiliary stiffener, within a semiconductor assembly, according to various aspects of the present disclosure.

FIG. 5B is a side view of FIG. 5A taken along line C-C′, according to various aspects of the present disclosure.

According to various aspects, there may be provided the stiffener assembly 500.

According to various aspects, the stiffener assembly 500 may contain any one or more or all the features and/or limitations of the stiffener assembly 100 of FIG. 1A to FIG. 1C and/or the stiffener assembly 200 of FIG. 2A and FIG. 2B. In the following, the stiffener assembly 500 is described with like reference characters generally referring to the same or corresponding parts/features of the stiffener assembly 100 of FIG. 1A to FIG. 1C and/or the stiffener assembly 200 of FIG. 2A and FIG. 2B. The description of the parts/features made with respect to the stiffener assembly 500 may also be applicable with respect to the stiffener assembly 100 and/or the stiffener assembly 200, and vice versa.

Referring to FIG. 5B, the stiffener assembly 500 may include a primary stiffener 510. As shown, the primary stiffener 510 may be disposed on a substrate 501 (e.g. a package substrate) to provide mechanical support to the substrate 501.

The stiffener assembly 500 may include (e.g. optionally include) the third variant auxiliary stiffener 520. The third variant auxiliary stiffener 520 may include or may be composed of a plurality (e.g. a pair or more) of auxiliary stiffener modules 520AA, 520BB detachably attachable (or attached) to the primary stiffener 510 for reinforcing the primary stiffener 510 (e.g. respective segments of the primary stiffener 510).

One or more dimensions (e.g. size, height, width, etc.) of each auxiliary stiffener module 520AA, 520BB, of the third variant auxiliary stiffener 520, may be scalable or configurable based on warpage prevention requirements to the primary stiffener 510 (or a respective segment of the primary stiffener 510 that requires reinforcement by the respective auxiliary stiffener module 520AA. 520BB) and, in turn, of the substrate 501 that the primary stiffener 510 may be disposed on. For instance, with reference to FIG. 5B, according to various aspects, an overall (or largest) height or thickness of each auxiliary stiffener module 520AA, 520BB may be larger or taller than a height or thickness of the primary stiffener 510 (i.e. measured along a direction perpendicular to a base surface of each stiffener/module 510, 520AA, 520BB, e.g. along the z-axis). Further, a width of wall(s) (e.g. side wall(s)) of each auxiliary stiffener module 520AA, 520BB may be larger than a width of corresponding or vertically aligned wall(s) of the primary stiffener 510 (i.e. measured along a direction parallel with a base surface of each stiffener/module 510, 520AA, 520BB, e.g. along the x-axis or the y-axis depending on an orientation of the width being measured). In particular, when the auxiliary stiffener module 520AA, 520BB is detachably attached to the primary stiffener 510, with the wall(s) of the auxiliary stiffener module 520AA, 520BB stacked on the corresponding wall(s) of the primary stiffener 510, an outer side portion 520b (at an outer wall surface) of the auxiliary stiffener module 520AA, 520BB may be cantilevered or extending sideways or protruding outwards away from an outer wall surface of the primary stiffener 510. Additionally, an inner side portion 520c (at an inner wall surface) of the auxiliary stiffener module 520AA, 520BB may be cantilevered or extending sideways or extending inwards of the stiffener assembly 500, away from an inner wall surface of the primary stiffener 510.

With reference to FIG. 5A and FIG. 5B, according to various aspects, when the auxiliary stiffener 520 (i.e. third variant auxiliary stiffener 520) includes the plurality of auxiliary stiffener modules 520AA, 520BB, the plurality of auxiliary stiffener modules 520AA, 520BB may be spaced apart from one another (e.g. along the upper portion of the primary stiffener 510). According to various aspects, the plurality of auxiliary stiffener modules 520AA, 520BB may be spaced apart from one another at equal (or regular) intervals, or at non-equal (or irregular) intervals, from one another. According to various aspects, each auxiliary stiffener module 520AA, 520BB of a plurality of auxiliary stiffener modules 520AA, 520BB may be configured (e.g. sized) to reinforce a respective segment or portion of the primary stiffener 510. In other words, according to various aspects, the plurality of auxiliary stiffener modules 520AA, 520BB may be arranged with respect to the primary stiffener 510 in a manner so as to reinforce various (in other words, a plurality of) corresponding segments or portions of the primary stiffener 510. According to various aspects, each auxiliary stiffener module 520AA, 520BB may extend over and/or along an entire length of one or more wall(s) of the primary stiffener 510. Additionally, or alternatively, each auxiliary stiffener module 520AA, 520BB may extend over and/or along a segment or portion of one or more wall(s) (e.g. one or more other, e.g. neighboring or adjacent, wall(s)) of the primary stiffener 510. In other words, according to various aspects, a length of each auxiliary stiffener module 520AA, 520BB may be equal to, or shorter than or longer than, a length of a corresponding wall of the primary stiffener 510 (i.e. where the auxiliary stiffener module 520AA, 520BB may be detachably attached to). As a non-limiting example, as shown in FIG. 5A, each auxiliary stiffener module 520AA, 520BB, of the auxiliary stiffener 520 (i.e. third variant auxiliary stiffener 520), may partially extend along a perimeter of the plurality of adjoining walls (i.e. circumferential structure) of the primary stiffener 510. More specifically, each auxiliary stiffener module 520AA, 520BB, of the auxiliary stiffener 520 (i.e. third variant auxiliary stiffener 520), may be bracket-shaped (e.g. “[”-shaped), such that it extends over and along an entire length of one wall (e.g. one lateral side wall) as well as over and along adjacent segments of a pair of neighboring walls (e.g. segments of longitudinal side walls, which are adjacent to and adjoining the lateral side wall). As shown, a pair of the (bracket-shaped) auxiliary stiffener modules 520AA, 520BB, of the third variant auxiliary stiffener 520, may be spaced apart from each other in an opposing manner to reinforce opposing (or opposite) segments or portions of the primary stiffener 510.

According to various aspects, the third variant auxiliary stiffener 520 may be detached from the primary stiffener 510 when no longer required. Subsequently, it may be detachably attached to another primary stiffener 510 having the first engagement arrangement 530 (i.e. that is configured to be detachably engaged with the second engagement arrangement 540 of the third variant auxiliary stiffener 520). Accordingly, the stiffener assembly 500, according to the various aspects, may offer a reusable auxiliary stiffener 520.

According to various aspects, the substrate 501 and the stiffener assembly 500 (e.g. at least the primary stiffener 510 of the stiffener assembly 500), may collectively form or be part of a semiconductor assembly 5001.

As shown, the primary stiffener 510 may be a circumferential structure, that extends over the substrate-surface, along (e.g. along only) a peripheral region of the substrate 501. More specifically, the primary stiffener 510 may include a plurality of adjoining walls, adjoined end-to-end to surround a central space, on the substrate-surface.

The semiconductor assembly 5001 may include (e.g. further include) one or more semiconductor devices (e.g. which may include dies) within the central space on the substrate-surface of the substrate 501. As a non-limiting example, shown in FIG. 5B, the one or more semiconductor devices may include at least one base die 551 disposed on the substrate-surface and at least one other die (e.g. three other dies 552) disposed on or stacked on the base die 551.

A tallest point (e.g. relative to the substrate-surface of the substrate 501) of the one or more semiconductor devices on the substrate-surface (e.g. the topmost surface of the one other die 552, i.e. that is stacked on the base die 551) may be further away from the substrate-surface of the substrate 501 than an upper (or topmost) surface of the primary stiffener 510. Thus, when the third variant auxiliary stiffener 520 is detached from the primary stiffener 510, the primary stiffener 510 may not interfere nor come into contact with a heat spreader (e.g. substantially flat heat spreader) that may be subsequently placed on the one or more semiconductor devices (or on at least the topmost surface of the one other die 552).

According to various aspects, with reference to FIG. 5B, the semiconductor assembly 5001 may include (e.g. further include) a circuit board 560 (e.g. a main circuit board, motherboard, printed circuit board, etc.). The substrate 501 may be disposed over the circuit board 560 and may be connected to the circuit board 560 via a first interconnect member 570a and a second interconnect member 570b, with the first interconnect member 570a and the second interconnect member 570b sandwiched between the circuit board 560 and the substrate 501. The first interconnect member 570a may include or may be made of a first material (or material composition, e.g. an alloy), and the second interconnect member 570b may include or may be made of a second material (or material composition). According to various aspects, the first material (or material composition) may be harder than the second material (or material composition). According to various aspects, at least the second material (or each of the first material and the second material) may include or may be an electrically conductive material. Accordingly, the first interconnect member 570a, made of a harder material, may be strategically placed on the circuit board 560 to prevent squash or deformation (e.g. of the substrate 501, the circuit board 560, and the second interconnect member 570b). As an example, shown in FIG. 5B, the first interconnect member 570a may include or may be at least one solder ball (e.g. of a BGA), and the second interconnect member 570b may include or may be at least one other solder ball (e.g. of another BGA). The at least one solder ball of the first interconnect member 570a may be positioned below (e.g. directly below), in other words, may be aligned (e.g. vertically aligned) with, the primary stiffener 510. For example, the at least one solder ball of the first interconnect member 570a may be disposed or distributed around a peripheral region of the substrate 501 at its base surface, opposite the substrate-surface of the substrate 501. Specifically, at least one solder ball of the first interconnect member 570a may be disposed, at least, below the first engagement arrangement 530 (e.g. below each detachable connector of the first engagement arrangement 530). As a further example, at least one solder ball of the first interconnect member 570a may be disposed below (in other words, opposite) the central space (i.e. where one or more dies 551, 552 may be disposed). In this manner, the harder first interconnect member 570a may prevent squash when the third variant auxiliary stiffener 520 is detachably attached onto the primary stiffener 510 and/or during a mounting process, surface mount process, reflow process, etc.

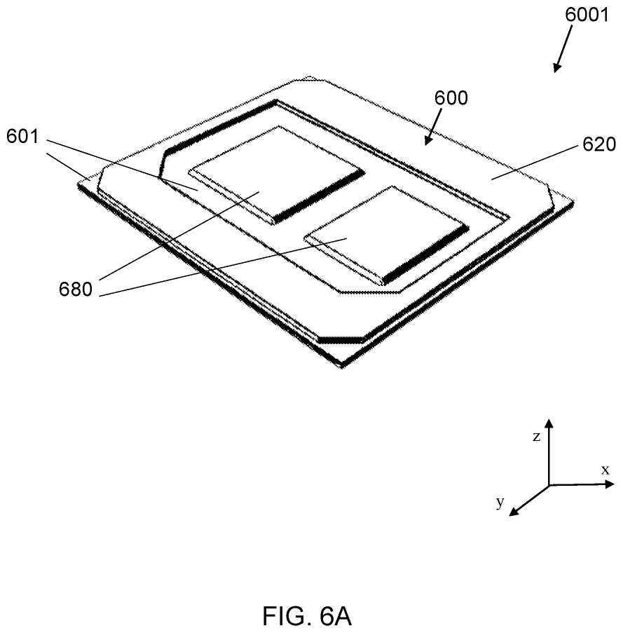

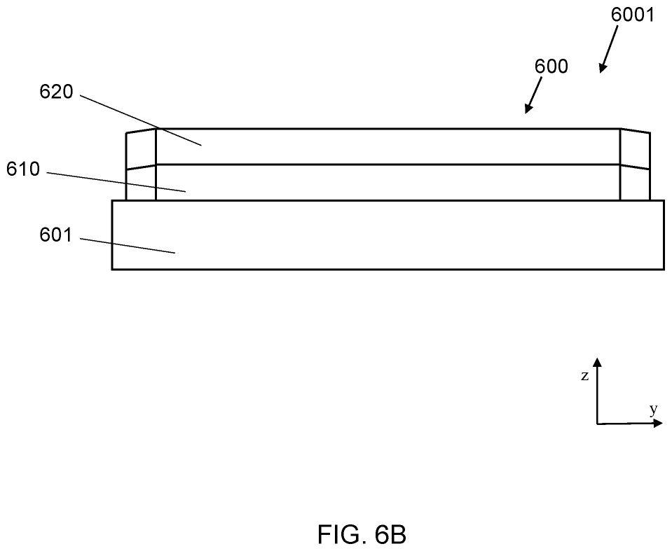

FIG. 6A shows a top perspective view of a stiffener assembly with a primary stiffener and an auxiliary stiffener having chamfered corner walls, within a semiconductor assembly, according to various aspects of the present disclosure.

FIG. 6B is a side view of FIG. 6A, according to various aspects of the present disclosure.

According to various aspects, there may be provided the stiffener assembly 600.

According to various aspects, the stiffener assembly 600 may contain any one or more or all the features and/or limitations of the stiffener assembly 100 of FIG. 1A to FIG. 1C and/or the stiffener assembly 200 of FIG. 2A and FIG. 2B and/or the stiffener assembly 300, 400, or 500 of FIG. 3A to FIG. 5B. In the following, the stiffener assembly 600 is described with like reference characters generally referring to the same or corresponding parts/features of the stiffener assembly 100 of FIG. 1A to FIG. 1C and/or the stiffener assembly 200 of FIG. 2A and FIG. 2B and/or the stiffener assembly 300, 400, or 500 of FIG. 3A to FIG. 5B. The description of the parts/features made with respect to the stiffener assembly 600 may also be applicable with respect to the stiffener assembly 100 and/or the stiffener assembly 200 and/or the stiffener assembly 300, 400 or 500, and vice versa.

Referring to FIG. 6A and FIG. 6B, the stiffener assembly 600 may include a primary stiffener 610 and an auxiliary stiffener 620 detachably attachable (or attached) to the primary stiffener 610 to reinforce the primary stiffener 610. The stiffener assembly 600 may be attached to a substrate 601 to reinforce the substrate 601 against potential deformation (e.g. warpage), for example, when heated during surface mount or reflow processes.

As shown, each of the primary stiffener 610 and the auxiliary stiffener 620 may include a chamfered corner wall between a pair (or each pair) of side walls thereof. As shown, the pair of side walls may be perpendicular (e.g. substantially perpendicular) to each other. As a non-limiting example, shown in FIG. 6A, each of the primary stiffener 610 and the auxiliary stiffener 620 may include four chamfered corner walls and two pairs of side walls (i.e. (i) a first pair of parallel side walls and (ii) a second pair of parallel side walls which may be perpendicular or substantial perpendicular to the first pair of parallel side walls).

According to various aspects, the substrate 601 and the stiffener assembly 600 (e.g. at least the primary stiffener 610 of the stiffener assembly 600), may collectively form or be part of a semiconductor assembly 6001.

As shown in FIG. 6A, the primary stiffener 610 may be a circumferential structure, on a substrate-surface (e.g. upper surface) of the substrate 601, along a peripheral region of the substrate 601. More specifically, the primary stiffener 610 may include a plurality of adjoining walls, adjoined end-to-end to surround a central space, on the substrate-surface.

The semiconductor assembly 6001 may include (e.g. further include) one or more semiconductor devices 680 (e.g. which may include dies) within the central space on the substrate-surface. As a non-limiting example, shown in FIG. 6B, the one or more semiconductor devices 680 may include a pair of adjacent or parallel dies on the substrate-surface of the substrate 601.

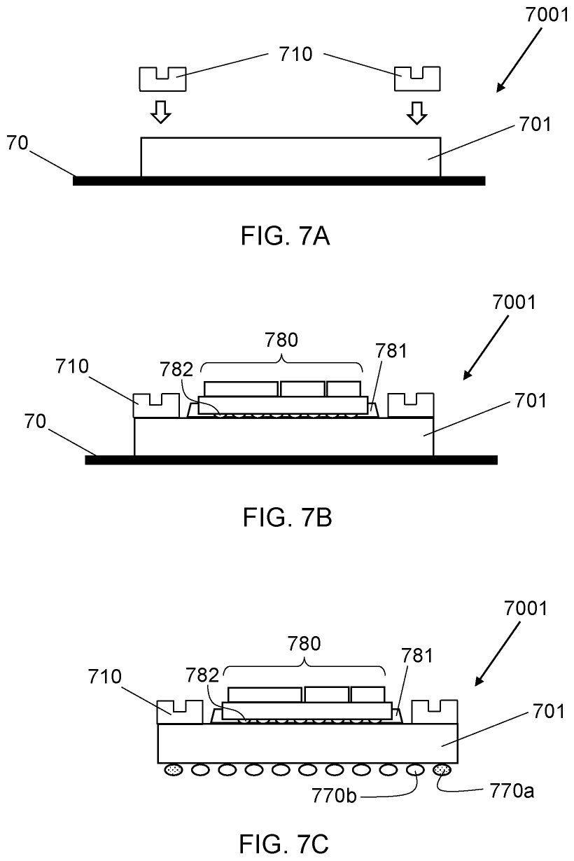

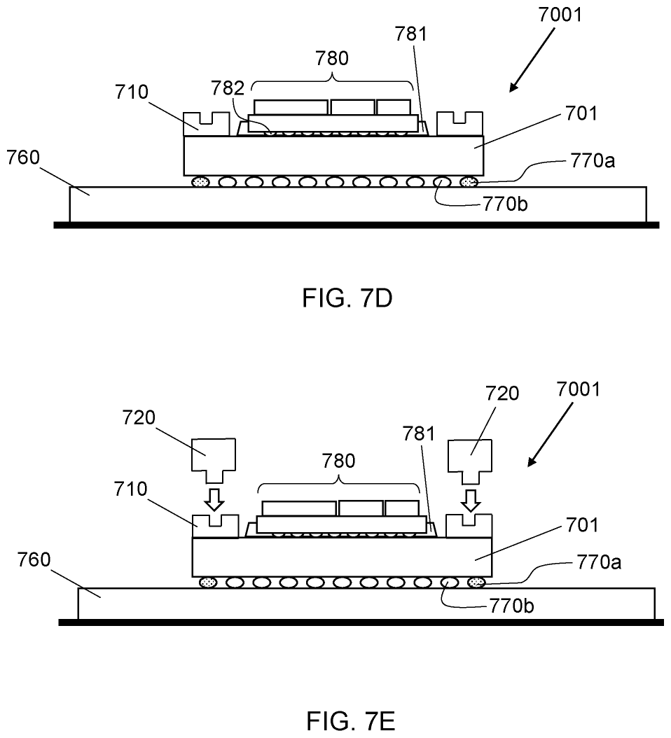

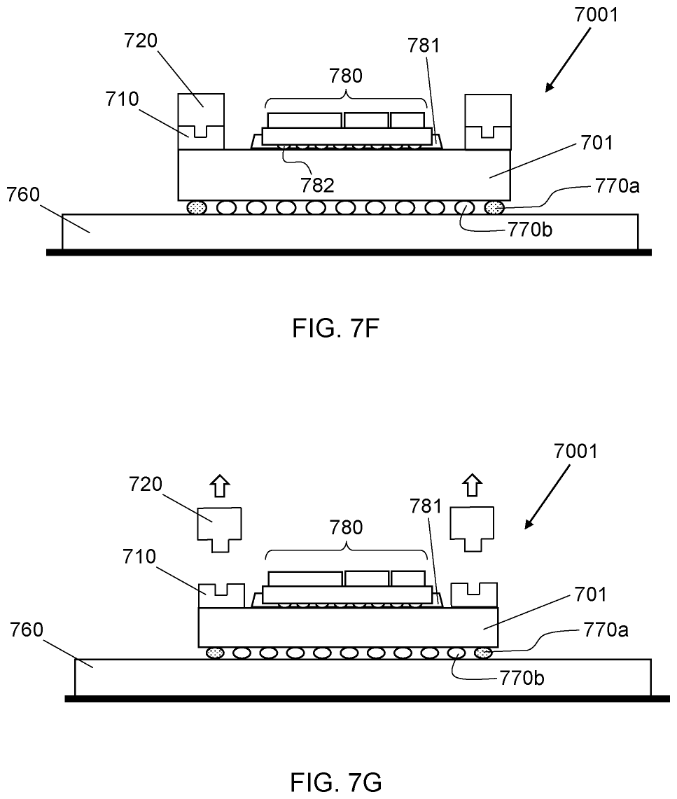

FIG. 7A to FIG. 7G depict a method or process for assembling a semiconductor assembly, according to various aspects of the present disclosure.

With reference to FIG. 7A, a substrate 701 (e.g. a package substrate) for a semiconductor assembly 7001 may be provided on a carrier 70. A primary stiffener 710 may be attached to a surface (i.e. “substrate-surface”, e.g. upper surface) of the substrate 701 (e.g. a package substrate), for example, via a “surface mounting process”.

With reference to FIG. 7B, thereafter, one or more semiconductor devices 780 (e.g. which may include one or more silicon dies) may be attached to the substrate-surface of the substrate 701 and an underfill layer 781 may be provided, for example, via “thermal compression bonding process”, “solder reflow process”, and “dispensing process”.

With reference to FIG. 7C, thereafter, the carrier 70 may be removed and, further, interconnect members 782, such as solder balls (e.g. copper solder balls, and/or Tin-Silver-Copper/SAC solder balls), may be attached to an underside (e.g. a base surface, opposite the substrate-surface) of the substrate 701 of the semiconductor assembly 7001, for example, via a “solder reflow process”.

With reference to FIG. 7D, thereafter, the substrate 701 (e.g. assembled package substrate) may be attached to a circuit board 760 (e.g. a motherboard) of the semiconductor assembly 7001, with interconnect members 770a, 770b interconnecting the substrate 701 and the circuit board 760, for example, via a “surface mounting process”.

With reference to FIG. 7E, thereafter, an auxiliary stiffener 720 may be detachably attached or releasably connected to the primary stiffener 710, with the auxiliary stiffener 720 over or on the primary stiffener 710, for example, via a “surface mounting process”.

With reference to FIG. 7F, thereafter, a “Surface Mounting Technology process” (e.g. a “reflow process”) may be performed or conducted.

With reference to FIG. 7G, thereafter, the auxiliary stiffener 720 may be detached or removed from the primary stiffener 710 (or from the semiconductor assembly 7001), for example, via a “removal process”. The removal process may utilize automated or robotic arms (not shown) for lifting the auxiliary stiffener 720 away from the primary stiffener 710.

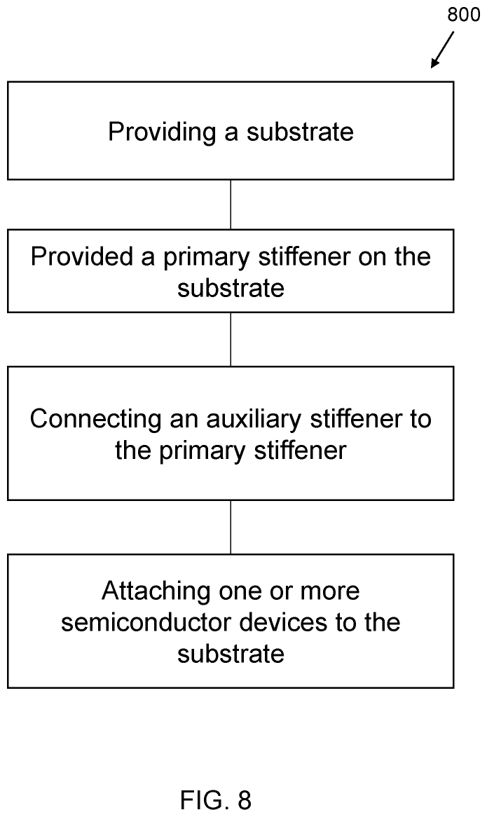

FIG. 8 is a flow chart of a method, according to various aspects of the present disclosure.

According to various aspects, the method 800 may be a method for making the semiconductor assembly 1001, 2001, 3001, 4001, 5001, 6001, or 7001.

According to various aspects, the method may include providing the substrate (e.g. a package substrate) 101, 201, 301, 401, 501, 601, or 701. According to various aspects, the substrate 101, 201, 301, 401, 501, 601, or 701 may constitute part of the semiconductor assembly 1001, 2001, 3001, 4001, 5001, 6001, or 7001.

According to various aspects, the method may include (e.g. further include) provided the primary stiffener 110, 210, 310, 410, 510, 610, or 710. According to various aspects, the primary stiffener 110, 210, 310, 410, 510, 610, or 710 may constitute part of the semiconductor assembly 1001, 2001, 3001, 4001, 5001, 6001, or 7001. The primary stiffener 110, 210, 310, 410, 510, 610, or 710 may include the first engagement arrangement 130, 230, 330, 430, or 530 at the upper portion of the primary stiffener 110, 210, 310, 410, 510, 610, or 710.

According to various aspects, the method may include (e.g. further include) affixing or attaching or mounting the primary stiffener 110, 210, 310, 410, 510, 610, or 710 to (e.g. directly onto) the substrate-surface (e.g. upper surface) of the substrate 101, 201, 301, 401, 501, 601, or 701, with the base portion (e.g. base surface) of the primary stiffener 110, 210, 310, 410, 510, 610, or 710 directed towards the substrate-surface of the substrate 101, 201, 301, 401, 501, 601, or 701.

According to various aspects, the method may include (e.g. further include) providing the auxiliary stiffener 120, 220, 320, 420, 520, 620, or 720. According to various aspects, the auxiliary stiffener 120, 220, 320, 420, 520, 620, or 720 may (e.g. may optionally) constitute part of the semiconductor assembly 1001, 2001, 3001, 4001, 5001, 6001, or 7001. The auxiliary stiffener 120, 220, 320, 420, 520, 620, or 720 may include the second engagement arrangement 140, 240, 340, 440, or 540 at the base portion of the auxiliary stiffener 120, 220, 320, 420, 520, 620, or 720.

According to various aspects, the method may include (e.g. further include) releasably connecting (e.g. detachably attaching) the auxiliary stiffener 120, 220, 320, 420, 520, 620, or 720 to the primary stiffener 110, 210, 310, 410, 510, 610, or 710, by engaging the second engagement arrangement 140, 240, 340, 440, or 540 of the auxiliary stiffener 120, 220, 320, 420, 520, 620, or 720 with the first engagement arrangement 130, 230, 330, 430, or 530 of the primary stiffener 110, 210, 310, 410, 510, 610, or 710.

According to various aspects, the method may include (e.g. further include) attaching or mounting (e.g. surface mounting) one or more semiconductor devices 180, 280, or 680 (e.g. which may include one or more dies) onto the substrate-surface of the substrate 101, 201, 301, 401, 501, 601, or 701. According to various aspects, the one or more semiconductor devices 180, 280, or 680 (or dies) may constitute part of the semiconductor assembly 1001, 2001, 3001, 4001, 5001, 6001, or 7001. According to various aspects, attaching or mounting (e.g. surface mounting) the one or more semiconductor devices 180, 280, or 680 (e.g. which may include dies) onto the substrate-surface of the substrate 101, 201, 301, 401, 501, 601, or 701 may involve heating the substrate 101, 201, 301, 401, 501, 601, or 701 and/or the semiconductor devices 180, 280, or 680.

According to various aspects, attaching or mounting of the one or more semiconductor devices 180, 280, or 680 onto the substrate-surface of the substrate 101, 201, 301, 401, 501, 601, or 701 may be performed after (or when) the auxiliary stiffener 120, 220, 320, 420, 520, 620, or 720 is attached or connected to the primary stiffener 110, 210, 310, 410, 510, 610, or 710. In other words, according to various aspects, the releasable connection (or the detachable attachment) of the auxiliary stiffener 120, 220, 320, 420, 520, 620, or 720 to the primary stiffener 110, 210, 310, 410, 510, 610, or 710 may be performed before the attachment or the mounting of the one or more semiconductor devices 180, 280, or 680 (or dies) onto the substrate-surface of the substrate 101, 201, 301, 401, 501, 601, or 701.

According to various aspects, the method may include (e.g. further include) detaching or removing the auxiliary stiffener 120, 220, 320, 420, 520, 620, or 720 from the primary stiffener 110, 210, 310, 410, 510, 610, or 710. In particular, the auxiliary stiffener 120, 220, 320, 420, 520, 620, or 720 may be detached or removed from the primary stiffener 110, 210, 310, 410, 510, 610, or 710 after the attachment or the mounting of the one or more semiconductor devices 180, 280, or 680 (or dies) onto the substrate-surface of the substrate 101, 201, 301, 401, 501, 601, or 701.

According to various aspects, the method may include (e.g. further include) engaging a heat spreader with the one or more semiconductor devices 180, 280, or 680 (or dies). According to various aspects, the heat spreader may constitute part of the semiconductor assembly 1001, 2001, 3001, 4001, 5001, 6001, or 7001.

According to various aspects, the method may include (e.g. further include) providing the circuit board (e.g. motherboard) 160, 360, 460, 560, or 760. According to various aspects, the circuit board 160, 360, 460, 560, or 760 may constitute part of the semiconductor assembly 1001, 2001, 3001, 4001, 5001, 6001, or 7001. The method may include disposing or stacking the substrate 101, 201, 301, 401, 501, 601, or 701 on or over the circuit board 160, 360, 460, 560, or 760, with a base surface of the substrate 101, 201, 301, 401, 501, 601, or 701 directed towards the circuit board 160, 360, 460, 560, or 760, and the method may include (e.g. further include) connecting the substrate 101, 201, 301, 401, 501, 601, or 701 to the circuit board 160, 360, 460, 560, or 760 via the first interconnect member 170a, 370a, 470a, 570a, or 770a and the second interconnect member 170b, 370b, 470b, 570b, or 770b between the substrate 101, 201, 301, 401, 501, 601, or 701 and the circuit board 160, 360, 460, 560, or 760. According to various aspects, the first interconnect member 170a, 370a, 470a, 570a, or 770a and the second interconnect member 170b, 370b, 470b, 570b, or 770b may also constitute part of the semiconductor assembly 1001, 2001, 3001, 4001, 5001, 6001, or 7001.

According to various other aspects, the method may include (e.g. further include) providing a further (e.g. another) primary stiffener 110, 210, 310, 410, 510, 610, or 710.

According to various other aspects, the method may include (e.g. further include) releasably connecting (e.g. detachably attaching) the auxiliary stiffener 120, 220, 320, 420, 520, 620, or 720 to the further (e.g. other) primary stiffener 110, 210, 310, 410, 510, 610, or 710. By employing this approach, the auxiliary stiffener 120, 220, 320, 420, 520, 620, or 720 can be reused or utilized multiple times.

Various aspects thus generally described a multi-component stiffener assembly.

The multi-component stiffener assembly may include a combination of a thin-profile primary stiffener and detachable reinforcing arrangement (i.e. auxiliary stiffener) that offers mechanical support to a package substrate during stages such as Surface Mounting Technology processes.

Moreover, the ability to detach and reattach the reinforcing arrangement relative to the primary stiffener enhances convenience and enables a relatively thin end product profile. This approach may not only improve the mechanical integrity of the package substrate but may also offer versatility, reusability, and cost-effectiveness.

Thus, by utilizing the multi-component stiffener assembly, according to the various aspects, semiconductor manufacturers may achieve robust and compact packaging solutions that meet the demands of modern electronic devices.

To more readily understand and put into practical effect the present stiffener assembly, semiconductor assembly, and method, they will now be described by way of examples. For the sake of brevity, duplicate descriptions of features and properties may be omitted.

### Examples

Example 1 provides a stiffener assembly. The stiffener assembly may include a primary stiffener with a base portion configured to be attachable or connectable to a surface of a package substrate. The primary stiffener may include a first engagement arrangement at an upper portion of the primary stiffener opposite the base portion. The stiffener assembly may further include an auxiliary stiffener with a base portion which may include a second engagement arrangement. The first engagement arrangement of the primary stiffener and the second engagement arrangement of the auxiliary stiffener may be configured to engage each other to form a detachable joint that releasably connects the auxiliary stiffener to the primary stiffener.

Example 2 may include the stiffener assembly of example 1 and/or any other example disclosed herein, for which the first engagement arrangement may include at least one snap-fit connector, and for which the second engagement arrangement may include at least one corresponding snap-fit connector.

Example 3 may include the stiffener assembly of example 1 and/or any other example disclosed herein, for which the first engagement arrangement may include at least one female snap-fit connector recessed into or from an upper surface of the primary stiffener, and for which the second engagement arrangement may include at least one male snap-fit connector protruding from a base surface of the auxiliary stiffener.

Example 4 may include the stiffener assembly of example 1 and/or any other example disclosed herein, for which the primary stiffener may include a plurality of walls adjoined to one another in an end-to-end arrangement to surround a central space.

Example 5 may include the stiffener assembly of example 1 and/or any other example disclosed herein, for which the primary stiffener may include at least two linear walls adjoined to each other at an angle that forms a corner region of the primary stiffener, and for which the first engagement arrangement may be at the corner region of the primary stiffener.

Example 6 may include the stiffener assembly of example 1 and/or any other example disclosed herein, for which the auxiliary stiffener may include a plurality of auxiliary stiffener modules, each auxiliary stiffener module may include a respective base portion that forms part of the base portion of the auxiliary stiffener, and for which the second engagement arrangement may be at the base portions of the plurality of auxiliary stiffener modules.

Example 7 may include the stiffener assembly of example 6, for which the plurality of auxiliary stiffener modules may be spaced apart from one another.

Example 8 may include the stiffener assembly of example 6 or example 7, for which the primary stiffener may include a plurality of walls adjoined to one another in an end-to-end arrangement to surround a central space, and for which each auxiliary stiffener module may partially extend along a perimeter of the plurality of walls of the primary stiffener.

Example 9 may include the stiffener assembly of example 1 and/or any other example disclosed herein, for which a width of the auxiliary stiffener may be different from (e.g. smaller or larger than) a width of the primary stiffener, and/or for which a height (or thickness) the auxiliary stiffener may be different from (e.g. smaller or larger than) a height (or thickness) of the primary stiffener.

Example 10 may include the stiffener assembly of example 1 and/or any other example disclosed herein, for which the auxiliary stiffener may include an alignment element at the base portion of the auxiliary stiffener, and for which the primary stiffener may include a corresponding alignment element at the upper portion of the primary stiffener.

Example 11 may include the stiffener assembly of example 1 and/or any other example disclosed herein, for which the auxiliary stiffener is composed of a different material from the primary stiffener.

Example 12 provides a semiconductor assembly. The semiconductor assembly may include a package substrate, at least one semiconductor device on a surface of the package substrate, and a stiffener with a base portion attached to the surface of the package substrate. The stiffener may include an engagement arrangement at an upper portion of the stiffener opposite the base portion, and the engagement arrangement may be configured to detachably join an auxiliary stiffener to the stiffener.

Example 13 may include the semiconductor assembly of example 12 and/or any other example disclosed herein, for which the at least one semiconductor device includes at least one die.

Example 14 may include the semiconductor assembly of example 12 and/or any other example disclosed herein, for which a height (or thickness) of the stiffener relative to the surface of the package is equal to or shorter than a height (or thickness) of the at least one semiconductor device.

Example 15 may include the semiconductor assembly of example 13, which further includes a heat spreader in contact with the at least one die.

Example 16 may include the semiconductor assembly of example 12 and/or any other example disclosed herein, which further includes the auxiliary stiffener detachably attached to the stiffener.

Example 17 may include the semiconductor assembly of example 12 and/or any other example disclosed herein, which further includes a circuit board, wherein the package substrate may be stacked on or over the circuit board and may be connected to the circuit board via a first interconnect member and a second interconnect member between the circuit board and the package substrate. The first interconnect member may be composed of a harder material than the second interconnect member.

Example 18 provides a method (e.g. method for making a semiconductor assembly). The method may include providing a package substrate, providing a primary stiffener which may include a first engagement arrangement at an upper portion of the primary stiffener, attaching the primary stiffener to a surface of the package substrate, with a base portion of the primary stiffener directed towards the surface of the package substrate, providing an auxiliary stiffener which may include a second engagement arrangement at a base portion of the auxiliary stiffener, wherein the first engagement arrangement of the primary stiffener and the second engagement arrangement of the auxiliary stiffener may be configured to engage each other to form a detachable joint, releasably connecting the auxiliary stiffener to the primary stiffener by engaging the second engagement arrangement of the auxiliary stiffener with the first engagement arrangement of the primary stiffener, and attaching one or more semiconductor devices onto the surface of the package substrate.

Example 19 may include the method of example 18 and/or any other example disclosed herein, for which the auxiliary stiffener may be releasably connected to the primary stiffener before attaching the one or more semiconductor devices onto the surface of the package substrate.

Example 20 may include the method of example 18 and/or any other example disclosed herein, which further includes detaching the auxiliary stiffener from the primary stiffener after the attachment of the one or more semiconductor devices onto the surface of the package substrate.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The terms “and” and “or” herein may be understood to mean “and/or” as including either or both of two stated possibilities.

While the disclosure has been particularly shown and described with reference to specific aspects, it should be understood by those skilled in the art that various changes, modification, variation in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

1. A stiffener assembly comprising:
a primary stiffener with a base portion configured to be attachable to a surface of a package substrate;
wherein the primary stiffener comprises a first engagement arrangement at an upper portion of the primary stiffener opposite the base portion;
an auxiliary stiffener with a base portion comprising a second engagement arrangement;
wherein the first engagement arrangement of the primary stiffener and the second engagement arrangement of the auxiliary stiffener are configured to engage each other to form a detachable joint that releasably connects the auxiliary stiffener to the primary stiffener.

2. The stiffener assembly of claim 1,
wherein the first engagement arrangement comprises at least one snap-fit connector;
wherein the second engagement arrangement comprises at least one corresponding snap-fit connector.

3. The stiffener assembly of claim 1,
wherein the first engagement arrangement comprises at least one female snap-fit connector recessed from an upper surface of the primary stiffener;
wherein the second engagement arrangement comprises at least one male snap-fit connector protruding from a base surface of the auxiliary stiffener.

4. The stiffener assembly of claim 1,
wherein the primary stiffener comprises a plurality of walls adjoined to one another in an end-to-end arrangement to surround a central space.

5. The stiffener assembly of claim 1,
wherein the primary stiffener comprises at least two linear walls adjoined to each other at an angle that forms a corner region of the primary stiffener;
wherein the first engagement arrangement is at the corner region of the primary stiffener.

6. The stiffener assembly of claim 1,
wherein the auxiliary stiffener comprises a plurality of auxiliary stiffener modules, each auxiliary stiffener module comprising a respective base portion that forms part of the base portion of the auxiliary stiffener;
wherein the second engagement arrangement is at the base portions of the plurality of auxiliary stiffener modules.

7. The stiffener assembly of claim 6,
wherein the plurality of auxiliary stiffener modules are spaced apart from one another.

8. The stiffener assembly of claim 6,
wherein the primary stiffener comprises a plurality of walls adjoined to one another in an end-to-end arrangement to surround a central space;
wherein each auxiliary stiffener module partially extends along a perimeter of the plurality of walls of the primary stiffener.

9. The stiffener assembly of claim 1,
wherein a width of the auxiliary stiffener is larger than a width of the primary stiffener; or
wherein a thickness of the auxiliary stiffener is larger than a thickness of the primary stiffener.

10. The stiffener assembly of claim 1,
wherein the auxiliary stiffener comprises an alignment element at the base portion of the auxiliary stiffener;
wherein the primary stiffener comprises a corresponding alignment element at the upper portion of the primary stiffener.

11. The stiffener assembly of claim 1,
wherein the auxiliary stiffener is composed of a different material from the primary stiffener.

12. A semiconductor assembly comprising:
a package substrate;
at least one semiconductor device on a surface of the package substrate; and
a stiffener with a base portion attached to the surface of the package substrate;
wherein the stiffener comprises an engagement arrangement at an upper portion of the stiffener opposite the base portion, wherein the engagement arrangement is configured to detachably join an auxiliary stiffener to the stiffener.

13. The semiconductor assembly of claim 12,
wherein the at least one semiconductor device comprises at least one die.

14. The semiconductor assembly of claim 12,
wherein a height of the stiffener relative to the surface of the package is shorter than a height of the at least one semiconductor device.

15. The semiconductor assembly of claim 13, further comprising:
a heat spreader in contact with the at least one die.

16. The semiconductor assembly of claim 12, further comprising:
the auxiliary stiffener detachably attached to the stiffener.

17. The semiconductor assembly of claim 12, further comprising:
a circuit board;
wherein the package substrate is stacked over the circuit board and is connected to the circuit board via a first interconnect member and a second interconnect member between the circuit board and the package substrate;
wherein the first interconnect member is composed of a harder material than the second interconnect member.

18. A method comprising:
providing a package substrate;
providing a primary stiffener comprising a first engagement arrangement at an upper portion of the primary stiffener;
attaching the primary stiffener to a surface of the package substrate, with a base portion of the primary stiffener directed towards the surface of the package substrate;
providing an auxiliary stiffener comprising a second engagement arrangement at a base portion of the auxiliary stiffener, wherein the first engagement arrangement of the primary stiffener and the second engagement arrangement of the auxiliary stiffener are configured to engage each other to form a detachable joint;
releasably connecting the auxiliary stiffener to the primary stiffener by engaging the second engagement arrangement of the auxiliary stiffener with the first engagement arrangement of the primary stiffener; and
attaching one or more semiconductor devices onto the surface of the package substrate.

19. The method of claim 18,
wherein the auxiliary stiffener is releasably connected to the primary stiffener before attaching the one or more semiconductor devices onto the surface of the package substrate.

20. The method of claim 18, further comprising:
detaching the auxiliary stiffener from the primary stiffener after the attachment of the one or more semiconductor devices onto the surface of the package substrate.
